(19) United States
(12) Patent Application Publication
(10) Pub. No.: US 2025/0063788 A1
(43) Pub. Date: Feb. 20, 2025

(54) SEMICONDUCTOR DEVICE AND METHOD OF FABRICATING THE SAME

(71) Applicant: Samsung Electronics Co., Ltd., Suwon-si (KR)

(72) Inventors: Sang Min CHO, Suwon-si (KR); Hee Sub KIM, Suwon-si (KR); Bo Mi KIM, Suwon-si (KR); Chul Sung KIM, Suwon-si (KR); Geun Hee JEONG, Suwon-si (KR)

(73) Assignee: Samsung Electronics Co., Ltd., Suwon-si (KR)

(21) Appl. No.: 18/431,190

(22) Filed: Feb. 2, 2024

(30) Foreign Application Priority Data
Aug. 14, 2023 (KR) 10-2023-0106308

(51) Int. Cl. H01L 29/66; H01L 21/8234; H01L 27/088; H01L 29/06; H01L 29/08; H01L 29/423; H01L 29/775; H01L 29/786

(52) U.S. Cl. CPC H01L 29/66545; H01L 21/823418; H01L 21/823468; H01L 21/823475; H01L 27/088; H01L 29/0673; H01L 29/0847; H01L 29/42392; H01L 29/66439; H01L 29/6656; H01L 29/775; H01L 29/78696

(57) ABSTRACT

The semiconductor device includes a substrate, first and second active patterns extending in a first direction, the second active pattern spaced apart from the first active pattern in a second direction different from the first direction, a gate electrode extending in the second direction, a first and second source/drain region each on one side of the gate electrode, a first and second source/drain contact each extending in the second direction on and connected to the first and second source/drain region respectively, and a contact separation layer separating the first and second source/drain contacts, the contact separation layer including a first portion and a second portion on first portion both between the first and second source/drain regions, wherein a width of the first portion of the contact separation layer in the first direction is greater than a width of the second portion of the contact separation layer in the first direction.

### CROSS-REFERENCE TO RELATED APPLICATION

This application claims priority from Korean Patent Application No. 10-2023-0106308 filed on Aug. 14, 2023 in the Korean Intellectual Property Office, and all the benefits accruing therefrom under 35 U.S.C. 119, the contents of which in its entirety are herein incorporated by reference.

### BACKGROUND

The present disclosure relates to semiconductor devices and methods of fabricating the same, and more particularly, to semiconductor devices including a multi-bridge channel field-effect transistor (MBCFET™) and methods of fabricating the semiconductor device.

As a scaling technique for increasing the density of integrated circuit devices, the concept of a multi-gate transistor has been proposed in which a silicon body in the form of a fin or nanowire is formed on a substrate and a gate is formed on the surface of the silicon body.

The multi-gate transistor takes advantage of its three-dimensional (3D) channel, allowing for easy scaling both up and down. Additionally, the multi-gate transistor offers improved control over the current without the need to increase the gate length. Furthermore, the multi-gate transistor effectively mitigates the short channel effect (SCE), which is the phenomenon where the electric potential of a channel region is affected by the drain voltage.

### SUMMARY

Aspects of the present disclosure provide semiconductor devices and methods of fabricating the same, which can effectively separate two source/drain contacts by forming a contact separation layer to have a varying lower width.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor device, comprising a substrate, first and second active patterns extending in a first horizontal direction on the substrate, and the second active pattern spaced apart from the first active pattern in a second horizontal direction different from the first horizontal direction, a gate electrode extending in the second horizontal direction on the first and second active patterns, a first source/drain region on a side of the gate electrode on the first active pattern, a second source/drain region on a side of the gate electrode on the second active pattern, a first source/drain contact extending in the second horizontal direction on the first source/drain region, the first source/drain contact connected to the first source/drain region, a second source/drain contact extending in the second horizontal direction on the second source/drain region, the second source/drain contact connected to the second source/drain region, the second source/drain contact spaced apart from the first source/drain contact in the second horizontal direction, and a contact separation layer separating the first and second source/drain contacts, the contact separation layer including a first portion between the first and second source/drain regions, and a second portion on the first portion between the first and second source/drain regions, wherein a width of the first portion of the contact separation layer in the first horizontal direction is greater than a width of the second portion of the contact separation layer in the first horizontal direction.

According to an aspect of the present disclosure, there is provided a semiconductor device, comprising a substrate, first and second active patterns extending in a first horizontal direction on the substrate, the second active pattern spaced apart from the first active pattern in a second horizontal direction different from the first horizontal direction, a field insulating layer surrounding sidewalls of each of the first and second active patterns on the substrate, a gate electrode extending in the second horizontal direction on the first and second active patterns, a gate spacer extending in the second horizontal direction on both sidewalls of the gate electrode in the first horizontal direction, a first source/drain region on one side of the gate electrode on the first active pattern, a second source/drain region on one side of the gate electrode on the second active pattern, an etch stopper layer on sidewalls of each of the first and second source/drain regions in the second horizontal direction, sidewalls of the gate spacer and a top surface of the field insulating layer, a first source/drain contact extending in the second horizontal direction on the first source/drain region, the first source/drain contact connected to the first source/drain region, a second source/drain contact extending in the second horizontal direction on the second source/drain region, the second source/drain contact connected to the second source/drain region, the second source/drain contact spaced apart from the first source/drain contact in the second horizontal direction, a contact separation layer separating the first and second source/drain contacts, the contact separation layer including a first portion between the first and second source/drain regions, and a second portion on the first portion between the first and second source/drain regions, wherein a width of the first portion of the contact separation layer in the second horizontal direction is greater than a width of the second portion of the contact separation layer in the second horizontal direction, and a liner layer between the etch stopper layer and sidewalls of the second portion of the contact separation layer in the first horizontal direction.

According to an aspect of the present disclosure, there is provided a method of fabricating a semiconductor device, comprising forming first and second active patterns extended in a first horizontal direction on a substrate, the second active pattern spaced apart from the first active pattern in a second horizontal direction different from the first horizontal direction, forming a field insulating layer surrounding sidewalls of each of the first and second active patterns on the substrate, forming a dummy gate extended in the second horizontal direction on the first and second active patterns, forming a gate spacer extended in the second horizontal direction on both sidewalls of the dummy gate in the first horizontal direction, forming a first source/drain region on one side of the dummy gate on the first active pattern, and forming a second source/drain region on one side of the dummy gate on the second active pattern, forming an etch stopper layer on surfaces of the first and second source/drain regions, sidewalls of the gate spacer and a top surface of the field insulating layer, removing the dummy gate, forming a gate electrode in a region where the dummy gate is removed, forming a first trench exposing the etch stopper layer on the sidewalls of the gate spacer, between the first and second source/drain regions, forming a first liner layer along sidewalls and a bottom surface of the first trench, forming a second trench by partially etching an upper portion of the first liner layer such that a top surface of the first liner layer becomes lower than top surfaces of the first and second source/drain regions, forming a contact separation layer within the second trench, the contact separation layer including a first portion and a second portion disposed on the first portion, and forming a first source/drain contact extending in the second horizontal direction on the first source/drain region, and a second source/drain contact extending in the second horizontal direction on the second source/drain region, wherein the contact separation layer separates the first and second source/drain contacts, wherein a width of the first portion of the contact separation layer in the first horizontal direction is different from a width of the second portion of the contact separation layer in the first horizontal direction, and wherein a width of the first portion of the contact separation layer in the second horizontal direction is different from a width of the second portion of the contact separation layer in the second horizontal direction.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a layout view of a semiconductor device according to some example embodiments of the present disclosure;

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIG. 5 is a cross-sectional view taken along line C-C′ of FIG. 1;

FIG. 6 is a cross-sectional view taken along line D-D′ of FIG. 1;

FIGS. 7 through 48 are cross-sectional views illustrating intermediate steps of methods of fabricating semiconductor devices according to some example embodiments of the present disclosure;

FIG. 49 is a cross-sectional view of a semiconductor device according to some example embodiments of the present disclosure;

FIG. 50 is a cross-sectional view of a semiconductor device according to some example embodiments of the present disclosure;

FIGS. 51 and 52 are cross-sectional views of a semiconductor device according to some example embodiments of the present disclosure;

FIGS. 53 through 56 are cross-sectional views illustrating intermediate steps of methods of fabricating semiconductor devices according to some example embodiments of the present disclosure; and

FIGS. 57 through 61 are cross-sectional views illustrating intermediate steps of methods of fabricating a semiconductor devices according to some example embodiments of the present disclosure.

### DETAILED DESCRIPTION

A semiconductor device according to some example embodiments of the present disclosure will hereinafter be described as including a Multi-Bridge Channel Field Effect Transistor (MBCFET™) with nanosheets and a fin field-effect transistor (FinFET) featuring fin-type channel regions, but the present disclosure is not limited thereto. A semiconductor device according to other example embodiments of the present disclosure may include a tunneling field-effect transistor (FET), or a three-dimensional (3D) transistor. A semiconductor device according to other example embodiments of the present disclosure may include a bipolar junction transistor or a lateral double-diffused metal-oxide-semiconductor field-effect transistor (LDMOS).

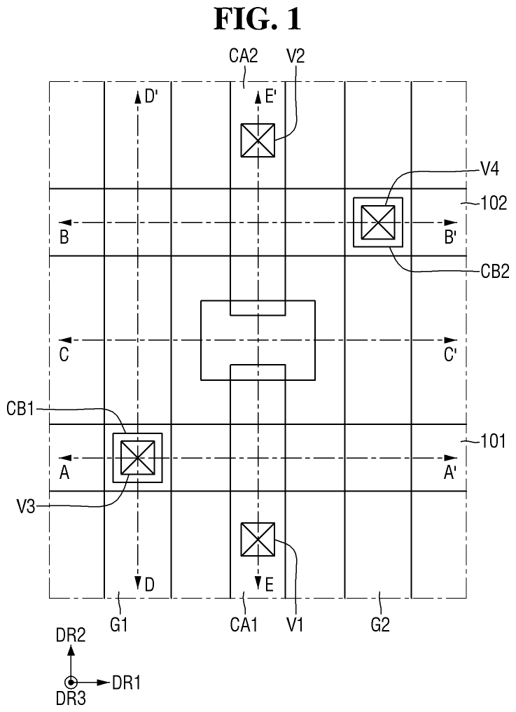

A semiconductor device according to some example embodiments of the present disclosure will hereinafter be described with reference to FIGS. 1 through 6.

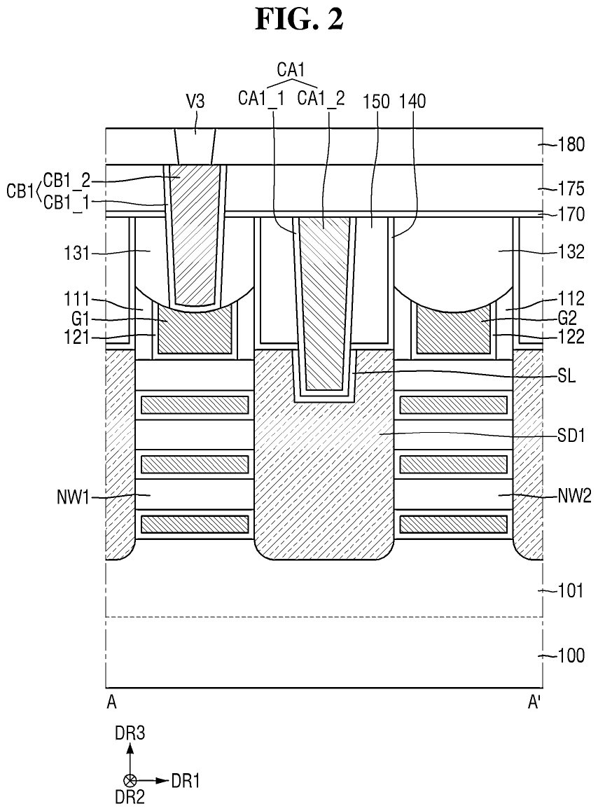

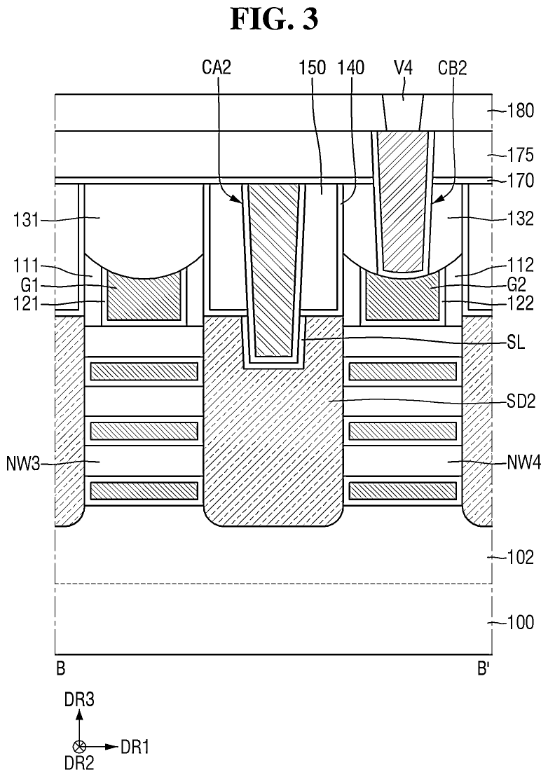

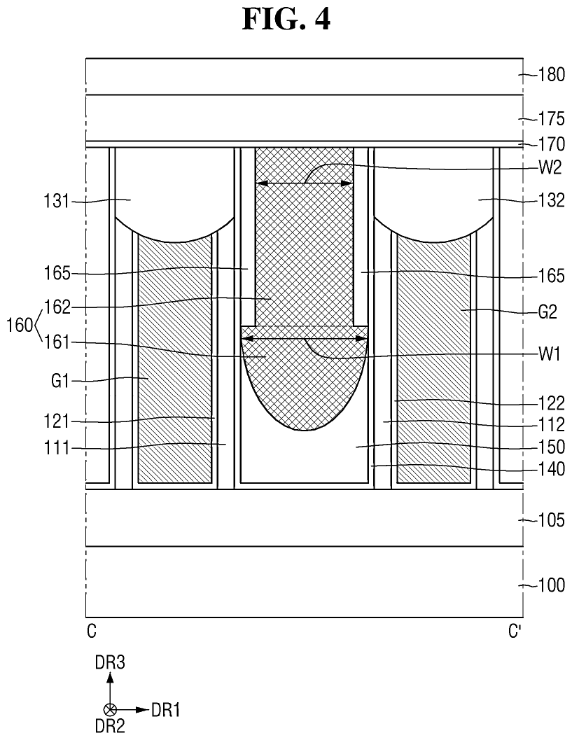

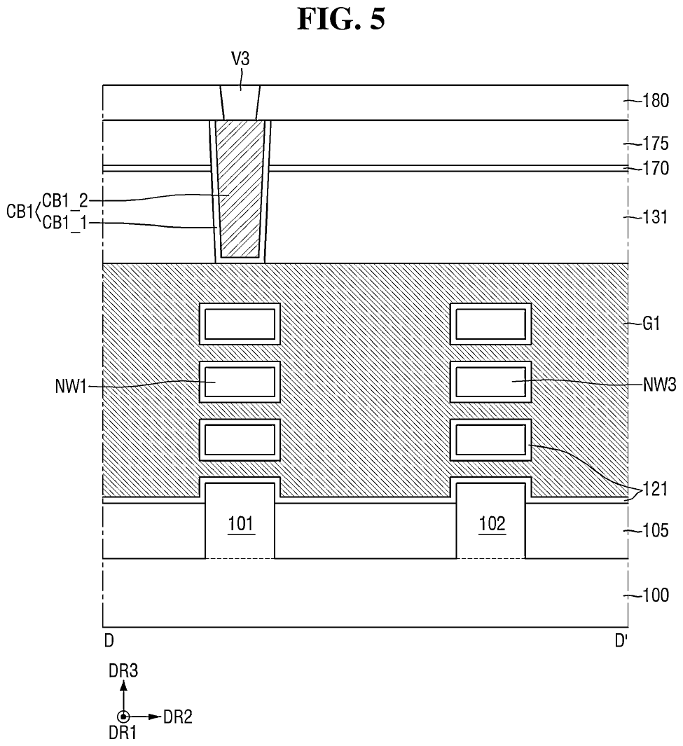

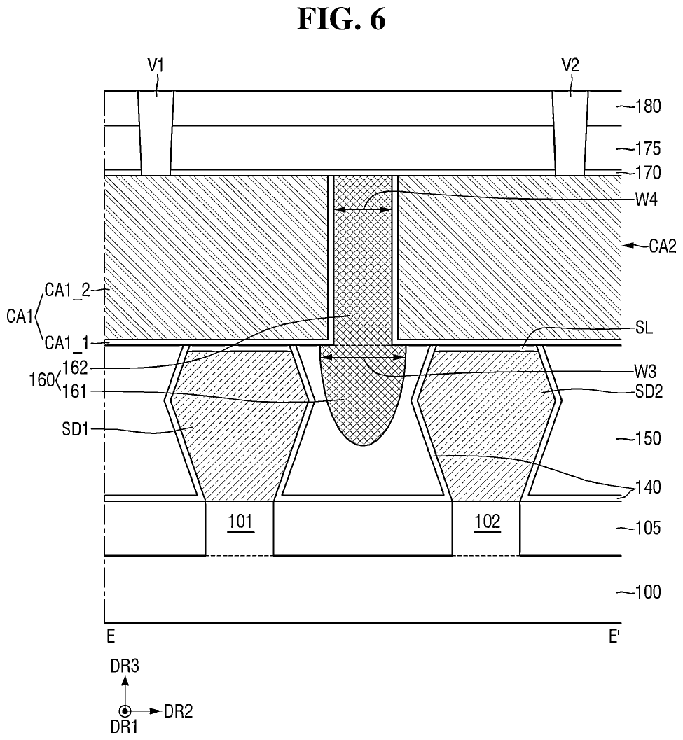

FIG. 1 is a layout view of a semiconductor device according to some example embodiments of the present disclosure. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1. FIG. 5 is a cross-sectional view taken along line C-C′ of FIG. 1. FIG. 6 is a cross-sectional view taken along line D-D′ of FIG. 1.

Referring to FIGS. 1 through 6, the semiconductor device according to some example embodiments of the present disclosure includes a substrate 100, first and second active patterns 101 and 102, a field insulating layer 105, a first plurality of nanosheets NW1, a second plurality of nanosheets NW2, a third plurality of nanosheets NW3, a fourth plurality of nanosheets NW4, first and second gate electrodes G1 and G2, first gate spacer 111, second gate spacer 112, first and second gate insulating layers 121 and 122, first and second capping patterns 131 and 132, first and second source/drain regions SD1 and SD2, a first etch stopper layer 140, a first interlayer insulating layer 150, first and second source/drain contacts CA1 and CA2, a silicide layer SL, a contact separation layer 160, a liner layer 165, a second etch stopper layer 170, a second interlayer insulating layer 175, first and second gate contacts CB1 and CB2, a third interlayer insulating layer 180, and first, second, third, and fourth vias V1, V2, V3, and V4.

The substrate 100 may be a silicon (Si) substrate or a silicon-on-insulator (SOI) substrate. Alternatively, the substrate 100 may include silicon-germanium (SiGe), silicon-germanium-on insulator (SGOI), indium antimonide, a lead tellurium compound, indium arsenide, indium phosphide, gallium arsenide, or gallium antimonide, but the present disclosure is not limited thereto.

First and second horizontal directions DR1 and DR2 may be defined as directions parallel to the top surface of the substrate 100. The second horizontal direction DR2 may be defined as a different direction from the first horizontal direction DR1. A vertical direction DR3 may be defined as a direction perpendicular to the first and second horizontal directions DR1 and DR2. That is, the vertical direction DR3 may be defined as being perpendicular to the top surface of the substrate 100.

The first and second active patterns 101 and 102 may extend in the first horizontal direction DR1 on the substrate 100. The second active pattern 102 may be spaced apart from the first active pattern 101 in the second horizontal direction DR2. The first and second active patterns 101 and 102 may protrude from the top surface of the substrate 100 in the vertical direction DR3. For example, the first and second active patterns 101 and 102 may be portions of the substrate 100 and may include epitaxial layers grown from the substrate 100.

The field insulating layer 105 may be disposed on the top surface of the substrate 100. The field insulating layer 105 may surround the sidewalls of each of the first and second active patterns 101 and 102. For example, the top surfaces of the first and second active patterns 101 and 102 may protrude beyond the top surface of the field insulating layer 105 in the vertical direction DR3, but the present disclosure is not limited thereto. Alternatively, in some example embodiments, the top surfaces of the first and second active patterns 101 and 102 may be formed on the same plane as the top surface of the field insulating layer 105. The field insulating layer 105 may include, for example, a silicon oxide film, a silicon nitride film, a silicon oxynitride film, or a combination thereof.

The first plurality of nanosheets NW1 may be disposed on the first active pattern 101. The first plurality of nanosheets NW1 may be disposed at the intersection between the first active pattern 101 and the first gate electrode G1. The second plurality of nanosheets NW2 may be disposed on the first active pattern 101. The second plurality of nanosheets NW2 may be disposed at the intersection between the first active pattern 101 and the second gate electrode G2. The second plurality of nanosheets NW2 may be spaced apart from the first plurality of nanosheets NW1 in the first horizontal direction DR1.

The third plurality of nanosheets NW3 may be disposed on the second active pattern 102. The third plurality of nanosheets NW3 may be disposed at the intersection between the second active pattern 102 and the first gate electrode G1. The third plurality of nanosheets NW3 may be spaced apart from the first plurality of nanosheets NW1 in the second horizontal direction DR2. The fourth plurality of nanosheets NW4 may be disposed on the second active pattern 102. The fourth plurality of nanosheets NW4 may be disposed at the intersection between the second active pattern 102 and the second gate electrode G2. The fourth plurality of nanosheets NW4 may be spaced apart from the third plurality of nanosheets NW3 in the first horizontal direction DR1. The fourth plurality of nanosheets NW4 may be spaced apart from the second plurality of nanosheets NW2 in the second horizontal direction DR2.

The first plurality of nanosheets NW1, the second plurality of nanosheets NW2, the third plurality of nanosheets NW3, and the fourth plurality of nanosheets NW4 may include a plurality of nanosheets that are stacked to be spaced apart in the vertical direction DR3. In the FIGS. 2 and 3, each of the first to fourth plurality of nanosheets NW1, NW2, NW3, NW4 includes three nanosheets that are provided to be spaced apart in the vertical direction DR3, but the present disclosure is not limited thereto. Alternatively, in some example embodiments, each of the first to fourth plurality of nanosheets NW1, NW2, NW3, NW4 may include at least four nanosheets that are provided to be spaced apart in the vertical direction DR3.

For example, the first plurality of nanosheets NW1, the second plurality of nanosheets NW2, the third plurality of nanosheets NW3, and the fourth plurality of nanosheets NW4 may include Si, but the present disclosure is not limited thereto. Alternatively, in some example embodiments, the first plurality of nanosheets NW1, the second plurality of nanosheets NW2, the third plurality of nanosheets NW3, and the fourth plurality of nanosheets NW4 may include SiGe.

The first gate electrode G1 may extend in the second horizontal direction DR2 on the first and second active patterns 101 and 102 and the field insulating layer 105. The first gate electrode G1 may surround each of the first plurality of nanosheets NW1 and third plurality of nanosheets NW3. The second gate electrode G2 may extend in the second horizontal direction DR2 on the first and second active patterns 101 and 102 and the field insulating layer 105. The second gate electrode G2 may be spaced apart from the first gate electrode G1 in the first horizontal direction DR1. The second gate electrode G2 may surround each of the second plurality of nanosheets NW2 and fourth plurality of nanosheets NW4.

The first and second gate electrodes G1 and G2 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but the present disclosure is not limited thereto. The first and second gate electrodes G1 and G2 may include a conductive metal oxide or a conductive metal oxynitride and may include oxidized forms of the aforementioned materials.

The first gate spacer 111 may extend along the top surface of the uppermost first nanosheet NW1, the top surface of the uppermost third nanosheet NW3, and the field insulating layer 105 along both sidewalls, in the first horizontal direction DR1, of the first gate electrode G1 in the second horizontal direction DR2. The second gate spacer 112 may extend along the top surface of the uppermost second nanosheet NW2, the top surface of the uppermost fourth nanosheet NW4, and the field insulating layer 105 along both sidewalls, in the first horizontal direction DR1, of the second gate electrode G2 in the second horizontal direction DR2.

The first gate spacer 111 and the second gate spacer 112 may include at least one of, for example, silicon nitride (SiN), silicon oxynitride (SiON), silicon dioxide (SiO₂), silicon oxycarbonitride (SiOCN), silicon boron nitride (SiBN), silicon oxiboron nitride (SiOBN), silicon oxycarbide (SiOC), and a combination thereof, but the present disclosure is not limited thereto.

The first gate insulating layer 121 may be disposed between the first gate electrode G1 and the first gate spacer 111. The first gate insulating layer 121 may be disposed on the sidewalls, in the first horizontal direction DR1, of the first gate electrode G1. The first gate insulating layer 121 may be disposed between the first gate electrode G1 and the first active pattern 101 and between the first gate electrode G1 and the second active pattern 102. The first gate insulating layer 121 may be disposed between the first gate electrode G1 and the field insulating layer 105. The first gate insulating layer 121 may be disposed between the first gate electrode G1 and the first plurality of nanosheets NW1 and between the first gate electrode G1 and the third plurality of nanosheets NW3.

The second gate insulating layer 122 may be disposed between the second gate electrode G2 and the second gate spacer 112. The second gate insulating layer 122 may be disposed on the sidewalls, spaced apart in the first horizontal direction DR1, of the second gate electrode G2. The second gate insulating layer 122 may be disposed between the second gate electrode G2 and the first active pattern 101 and between the second gate electrode G2 and the second active pattern 102. The second gate insulating layer 122 may be disposed between the second gate electrode G2 and the field insulating layer 105. The second gate insulating layer 122 may be disposed between the second gate electrode G2 and the second plurality of nanosheets NW2 and between the second gate electrode G2 and the fourth plurality of nanosheets NW4.

The first and second gate insulating layers 121 and 122 may include silicon oxide, silicon oxynitride, silicon nitride, or a high-k material with a greater dielectric constant than silicon oxide. The high-k material may include at least one of, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate.

The semiconductor device according to some example embodiments of the present disclosure may include a negative capacitance (NC) field-effect transistor (FET) using a negative capacitor. For example, each of the first and second gate insulating layers 121 and 122 may include a ferroelectric material film having ferroelectric properties and a paraelectric material film having paraelectric properties.

The ferroelectric material film may have a negative capacitance, and the paraelectric material film may have a positive capacitance. For example, if two or more capacitors are connected in series and have positive capacitance, the total capacitance of the two or more capacitors may be lower than the capacitance of each of the two or more capacitors. On the contrary, if at least one of the two or more capacitors has negative capacitance, the total capacitance of the two or more capacitors may have a positive value and may be greater than the absolute value of the capacitance of each of the two or more capacitors.

If the ferroelectric material film having a negative capacitance and the paraelectric material film having a positive capacitance are connected in series, the total capacitance of the ferroelectric material film and the paraelectric material film may increase. Accordingly, a transistor having the ferroelectric material film can have a sub-threshold swing (SS) of less than 60 mV/decade at room temperature.

The ferroelectric material film may have ferroelectric properties. The ferroelectric material film may include at least one of, for example, hafnium oxide, hafnium zirconium oxide, barium strontium titanium oxide, barium titanium oxide, and/or lead zirconium titanium oxide. For example, the hafnium zirconium oxide may be a material obtained by doping hafnium oxide with zirconium (Zr). In another example, the hafnium zirconium oxide may be a compound of hafnium (Hf), Zr, and oxygen (O).

The ferroelectric material film may further include a dopant. For example, the dopant may include at least one of Al, Ti, Nb, lanthanum (La), yttrium (Y), magnesium (Mg), silicon, calcium (Ca), cerium (Ce), dysprosium (Dy), erbium (Er), gadolinium (Gd), germanium, scandium (Sc), strontium (Sr), and/or tin (Sn). The type of dopant may vary depending on the type of material of the ferroelectric material film.

If the ferroelectric material film includes hafnium oxide, the dopant of the ferroelectric material film may include at least one of, for example, Gd, Si, Zr, Al, and/or Y.

If the dopant of the ferroelectric material film is Al, the ferroelectric material film may include about 3 atomic % (at %) to about 8 at % of Al. Here, the ratio of the dopant in the ferroelectric material film may refer to the ratio of the sum of the amounts of Hf and Al to the amount of Al in the ferroelectric material film.

If the dopant of the ferroelectric material film is Si, the ferroelectric material film may include about 2 at % to about 10 at % of Si. If the dopant of the ferroelectric material film is Y, the ferroelectric material film may include about 2 at % to about 10 at % of Y. If the dopant of the ferroelectric material film is Gd, the ferroelectric material film may include about 1 at % to about 7 at % of Gd. If the dopant of the ferroelectric material film is Zr, the ferroelectric material film may include about 50 at % to about 80 at % of Zr.

The paraelectric material film may include paraelectric properties. The paraelectric material film may include at least one of, for example, silicon oxide and a high-k metal oxide. The high-k metal oxide may include at least one of, for example, hafnium oxide, zirconium oxide, and aluminum oxide, but the present disclosure is not limited thereto.

The ferroelectric material film and the paraelectric material film may include the same material. The ferroelectric material film may have ferroelectric properties, but the paraelectric material film may not have ferroelectric properties. For example, if the ferroelectric material film and the paraelectric material film include hafnium oxide, the hafnium oxide included in the ferroelectric material film may have a different crystalline structure from the hafnium oxide included in the paraelectric material film.

The ferroelectric material film may be thick enough to exhibit ferroelectric properties. The ferroelectric material film may have a thickness of, for example, about 0.5 nm to about 10 nm, but the present disclosure is not limited thereto. A critical thickness that can exhibit ferroelectric properties may vary depending on the type of ferroelectric material, and thus, the thickness of the ferroelectric material film may vary depending on the type of ferroelectric material included in the ferroelectric material film.

For example, each of the first and second gate insulating layers 121 and 122 may include one ferroelectric material film. In another example, each of the first and second gate insulating layers 121 and 122 may include a plurality of ferroelectric material films that are spaced apart from one another. Each of the first and second gate insulating layers 121 and 122 may have a structure in which a plurality of ferroelectric material films and a plurality of paraelectric material films are stacked alternately.

The first capping pattern 131 may extend in the second horizontal direction DR2 on the first gate electrode G1, the first gate spacer 111, and the first gate insulating layer 121. The second capping pattern 132 may extend in the second horizontal direction DR2 on the second gate electrode G2, the second gate spacer 112, and the second gate insulating layer 122. The first and second capping patterns 131 and 132 may include at least one of, for example, SiN, SiON, SiO₂, SiCN, SiOCN, and/or a combination thereof, but the present disclosure is not limited thereto.

The first source/drain region SD1 may be disposed on at least one side of each of the first and second gate electrodes G1 and G2 on the first active pattern 101. For example, the first source/drain region SD1 may be disposed on both sides of each of the first and second gate electrodes G1 and G2 on the first active pattern 101. The second source/drain region SD2 may be disposed on at least one side of each of the first and second gate electrodes G1 and G2 on the second active pattern 102. For example, the second source/drain region SD2 may be disposed on both sides of each of the first and second gate electrodes G1 and G2 on the second active pattern 102.

For example, the first source/drain region SD1 may be in contact with both sidewalls, spaced apart in the first horizontal direction DR1, of each of the first plurality of nanosheets NW1 and second plurality of nanosheets NW2. For example, the second source/drain region SD2 may be in contact with both sidewalls, in the first horizontal direction DR1, of each of the third plurality of nanosheets NW3 and fourth plurality of nanosheets NW4. For example, each of the first and second source/drain regions SD1 and SD2 may be in contact with the first and second gate insulating layers 121 and 122, but the present disclosure is not limited thereto. Alternatively, in some example embodiments, inner spacers may be disposed between the first and second source/drain regions SD1 and SD2 and the first and second gate insulating layers 121 and 122. The inner spacers may include at least one of, for example, SiN, SiON, SiO₂, SiOCN, SiBN, SiOBN, SiOC, and a combination thereof.

The first interlayer insulating layer 150 may cover the first and second source/drain regions SD1 and SD2, on the field insulating layer 105. The first interlayer insulating layer 150 may surround the sidewalls of each of the first gate spacer 111 and second gate spacer 112 and the sidewalls of each of the first and second capping patterns 131 and 132. For example, the top surface of the first interlayer insulating layer 150 may be formed on the same plane as the top surfaces of the first and second capping patterns 131 and 132, but the present disclosure is not limited thereto.

The first interlayer insulating layer 150 may include at least one of, for example, silicon oxide, silicon nitride, silicon oxynitride, and/or a low-k material. The low-k material may include, for example, fluorinated tetraethyl orthosilicate (FTEOS), hydrogen silsesquioxane (HSQ), bis-benzocyclobutene (BCB), tetramethyl orthosilicate (TMOS), octamethylcyclotetrasiloxane (OMCTS), hexamethyldisiloxane (HMDS), trimethylsilyl borate (TMSB), diacetoxyditertiarybutosiloxane (DADBS), trimethylsilyl phosphate (TMSP), polytetrafluoroethylene (PTFE), tonen silazen (TOSZ), fluoride silicate glass (FSG), polyimide nanofoam (such as polypropylene oxide), carbon doped silicon oxide (CDO), organo silicate glass (OSG), SiLK, amorphous fluorinated carbon, silica aerogel, silica xerogel, mesoporous silica, and/or a combination thereof, but the present disclosure is not limited thereto.

The first etch stopper layer 140 may be disposed between the first interlayer insulating layer 150 and the field insulating layer 105. The first etch stopper layer 140 may be disposed between the first interlayer insulating layer 150 and the first and second source/drain regions SD1 and SD2. The first etch stopper layer 140 may be disposed between the first interlayer insulating layer 150 and the first gate spacer 111 and between the first interlayer insulating layer 150 and the second gate spacer 112. For example, the first etch stopper layer 140 may be disposed between the first interlayer insulating layer 150 and the first capping pattern 131 and between the first interlayer insulating layer 150 and the second capping pattern 132, but the present disclosure is not limited thereto. Alternatively, in some example embodiments, the first etch stopper layer 140 may not be disposed the first interlayer insulating layer 150 and the first capping pattern 131 and between the first interlayer insulating layer 150 and the second capping pattern 132. That is, the first interlayer insulating layer 150 may be in contact with the sidewalls of each of the first and second capping patterns 131 and 132. The first etch stopper layer 140 may include at least one of, for example, aluminum oxide, aluminum nitride, hafnium oxide, zirconium oxide, silicon oxide, silicon nitride, silicon oxynitride, and/or the low-k material.

The first source/drain contact CA1 may be disposed between the first and second gate electrodes G1 and G2. The first source/drain contact CA1 may extend in the second horizontal direction DR2 on the first source/drain region SD1. The first source/drain contact CA1 may be connected to the first source/drain region SD1. The second source/drain contact CA2 may be disposed between the first and second gate electrodes G1 and G2. The second source/drain contact CA2 may extend in the second horizontal direction DR2 on the second source/drain region SD2. The second source/drain contact CA2 may be spaced apart from the first source/drain contact CA1 in the second horizontal direction DR2. The second source/drain contact CA2 may be connected to the second source/drain region SD2.

FIGS. 2 and 3 illustrate that the first interlayer insulating layer 150 is disposed between the first source/drain contact CA1 and the first gate electrode G1 and between the second source/drain contact CA2 and the second gate electrode G2, but the present disclosure is not limited thereto. Alternatively, in some example embodiments, the first interlayer insulating layer 150 may not be disposed between the first source/drain contact CA1 and the first gate electrode G1 and between the second source/drain contact CA2 and the second gate electrode G2. For example, the top surfaces of the first source/drain contacts CA1 and CA2 may be formed on the same plane as the top surface of the first interlayer insulating layer 150, but the present disclosure is not limited thereto.

For example, each of the first and second source/drain contacts CA1 and CA1 may include a first contact barrier layer CA1_1 and a first contact filling layer CA1_2. The first contact barrier layer CA1_1 may form the sidewalls and bottom surface of each of the first and second source/drain contacts CA1 and CA2. The first contact filling layer CA1_2 may fill the inside of each of the first and second source/drain contacts CA1 and CA2 on the first contact barrier layer CA1_1. Alternatively, in some example embodiments, the first and second source/drain contacts CA1 and CA2 may be formed as single films.

The first contact barrier layer CA1_1 and the first contact filling layer CA1_2 may include a conductive material. The first contact barrier layer CA1_1 may include at least one of, for example, include Ta, TaN, Ti, TiN, Ru, Co, Ni, nickel boron (NiB), W, WN, tungsten carbonitride (WCN), Zr, zirconium nitride (ZrN), V, vanadium nitride (VN), Nb, NbN, Pt, Ir, and/or Rh. The first contact filling layer CA1_2 may include at least one of, for example, Al, W, Co, Ru, and/or Mo.

The silicide layer SL may be disposed along the boundary between the first source/drain region SD1 and the first source/drain contact CA1. The silicide layer SL may be disposed along the boundary between the second source/drain region SD2 and the second source/drain contact CA2. The silicide layer SL may include, for example, a metal silicide material.

The contact separation layer 160 may be disposed between the first and second gate electrodes G1 and G2. The contact separation layer 160 may be disposed between the first source/drain contact CA1 and the second source/drain contact CA2. The contact separation layer 160 may separate the first and second source/drain contacts CA1 and CA2 in the second horizontal direction DR2. For example, both sidewalls, in the second horizontal direction DR2, of the contact separation layer 160 may be in contact with the first and second source/drain contacts CA1 and CA2. For example, the contact separation layer 160 may be spaced apart from the first and second source/drain regions SD1 and SD2 in the second horizontal direction DR2.

For example, the bottom surface of the contact separation layer 160 may be formed to be lower than the bottom surfaces of the first and second source/drain contacts CA1 and CA2. For example, the bottom surface of the contact separation layer 160 may be spaced apart from the first etch stopper layer 140, which is disposed on the top surface of the field insulating layer 105, in the vertical direction DR3. The first interlayer insulating layer 150 may be disposed between the bottom surface of the contact separation layer 160 and the first etch stopper layer 140, which is disposed on the top surface of the field insulating layer 105. For example, the top surface of the contact separation layer 160 may be formed on the same plane as the top surfaces of the first and second source/drain contacts CA1 and CA2.

The contact separation layer 160 may include a first portion 161 and a second portion 162, which is disposed on the first portion 161. For convenience, the contact separation layer 160 is illustrated as being separated into the first and second portions 161 and 162, but alternatively, the first and second portions 161 and 162 of the contact separation layer 160 may be integrally formed.

The first portion 161 of the contact separation layer 160 may be disposed between the first and second source/drain regions SD1 and SD2. For example, both sidewalls, spaced apart in the first horizontal direction DR1, of the first portion 161 of the contact separation layer 160 may be in contact with the first etch stopper layer 140 on the sidewalls, in the first horizontal direction DR1, of each of the first gate spacer 111 and second gate spacer 112. For example, both sidewalls, spaced apart in the second horizontal direction DR2, of the first portion 161 of the contact separation layer 160 may be spaced apart from the first etch stopper layer 140 on the sidewalls, in the second horizontal direction DR2, of each of the first and second source/drain regions SD1 and SD2 in the second horizontal direction DR2. For example, at least portions of the top surface of the first portion 161 of the contact separation layer 160 may be in contact with the bottom surfaces of the first and second source/drain contacts CA1 and CA2. For example, the sidewalls and bottom surface of the first portion 161 of the contact separation layer 160 may be in contact with the first interlayer insulating layer 150.

The second portion 162 of the contact separation layer 160 may be disposed on the first portion 161 of the contact separation layer 160. The bottom surface of the second portion 162 of the contact separation layer 160 may be in contact with the top surface of the first portion 161 of the contact separation layer 160. The second portion 162 of the contact separation layer 160 may be disposed between the first and second source/drain contacts CA1 and CA2. For example, both sidewalls, spaced apart in the first horizontal direction DR1, of the second portion 162 of the contact separation layer 160 may be spaced apart from the first etch stopper layer 140 on the sidewalls, in the first horizontal direction DR1, of each of the first gate spacer 111 and second gate spacer 112 in the first horizontal direction DR1. For example, both sidewalls, spaced apart in the second horizontal direction DR2, of the second portion 162 of the contact separation layer 160 may be in contact with both sidewalls, in the second horizontal direction DR2, of each of the first and second source/drain contacts CA1 and CA2. For example, the top surface of the second portion 162 of the contact separation layer 160 may be formed on the same plane as the top surfaces of the first and second source/drain contacts CA1 and CA2.

A width W1, in the first horizontal direction DR1, of the first portion 161 of the contact separation layer 160 may differ from a width W2, in the first horizontal direction DR1, of the second portion 162 of the contact separation layer 160. For example, the width W1 may be greater than the width W2. A width W3, in the second horizontal direction DR2, of the first portion 161 of the contact separation layer 160 may differ from a width W4, in the second horizontal direction DR2, of the second portion 162 of the contact separation layer 160. For example, the width W3 may be greater than the width W4.

The contact separation layer 160 may include a different material from the first interlayer insulating layer 150. The first and second portions 161 and 162 of the contact separation layer 160 may include the same material. The contact separation layer 160 may include at least one of, for example, SiN, SiON, SiO₂, SiOCN, SiBN, SiOBN, SiOC, and/or a combination thereof, but the present disclosure is not limited thereto.

The liner layer 165 may be disposed between the first etch stopper layer 140 and both sidewalls, spaced apart in the first horizontal direction DR1, of the second portion 162 of the contact separation layer 160. For example, the liner layer 165 may be in contact with both sidewalls, spaced apart in the first horizontal direction DR1, of the second portion 162 of the contact separation layer 160 and the first etch stopper layer 140. For example, the liner layer 165 may be in contact with at least portions of the top surface of the first portion 161 of the contact separation layer 160. For example, the liner layer 165 may extend from the top surface of the first portion 161 of the contact separation layer 160 to the top surface of the second portion 162 of the contact separation layer 160. For example, the top surface of the liner layer 165 may be formed on the same plane as the top surface of the second portion 162 of the contact separation layer 160. For example, the liner layer 165 may include a different material from the contact separation layer 160. The liner layer 165 may include, SiO₂.

The second etch stopper layer 170 may be disposed on the top surfaces of the first interlayer insulating layer 150, the contact separation layer 160, the first and second source/drain contacts CA1 and CA2, and the first and second capping patterns 131 and 132. FIGS. 2 through 6 illustrate that the second etch stopper layer 170 is formed as a single film, but the present disclosure is not limited thereto. Alternatively, in some example embodiments, the second etch stopper layer 170 may be formed as a multifilm. The second etch stopper layer 170 may include at least one of, for example, aluminum oxide, aluminum nitride, hafnium oxide, zirconium oxide, silicon oxide, silicon nitride, silicon oxynitride, and/or the low-k material. The second interlayer insulating layer 175 may be disposed on the second etch stopper layer 170. The second interlayer insulating layer 175 may include at least one of, for example, silicon oxide, silicon nitride, silicon oxynitride, and/or the low-k material.

The first gate contact CB1 may be connected to the first gate electrode G1 by penetrating the second interlayer insulating layer 175, the second etch stopper layer 170, and the first capping pattern 131 in the vertical direction DR3. FIGS. 1 and 2 illustrate that the first gate contact CB1 overlaps with the first active pattern 101 in the vertical direction DR3, but the present disclosure is not limited thereto. The second gate contact CB2 may be connected to the second gate electrode G2 by penetrating the second interlayer insulating layer 175, the second etch stopper layer 170, and the second capping pattern 132 in the vertical direction DR3. FIGS. 1 and 3 illustrate that the second gate contact CB2 overlaps with the second active pattern 102 in the vertical direction DR3, but the present disclosure is not limited thereto.

For example, the top surfaces of the first and second gate contacts CB1 and CB2 may be formed on the same plane as the top surface of the second interlayer insulating layer 175, but the present disclosure is not limited thereto. Alternatively, in some example embodiments, the top surfaces of the first and second gate contacts CB1 and CB2 may be formed on the same plane as the top surfaces of the first and second capping patterns 131 and 132.

For example, each of the first and second gate contacts CB1 and CB2 may include a second contact barrier layer CB1_1 and a second contact filling layer CB1_2. The second contact barrier layer CB1_1 may form the sidewalls and bottom surface of each of the first and second gate contacts CB1 and CB2. The second contact filling layer CB1_2 may fill the inside of each of the first and second gate contacts CB1 and CB2 on the second contact barrier layer CB1_1. Alternatively, in some example embodiments, the first and second gate contacts CB1 and CB2 may be formed as single films.

The second contact barrier layer CB1_1 and the second contact filling layer CB1_2 may include a conductive material. The second contact barrier layer CB1_1 may include at least one of, for example, Ta, TaN, Ti, TiN, Ru, Co, Ni, NiB, W, WN, WCN, Zr, ZrN, V, VN, Nb, NbN, Pt, Ir, and/or Rh. The second contact filling layer CB1_2 may include at least one of, for example, Al, W, Co, Ru, and/or Mo.

The third interlayer insulating layer 180 may be disposed on the top surfaces of the first gate contact CB1, the second gate contact CB2, and the second interlayer insulating layer 175. The third interlayer insulating layer 180 may include at least one of, for example, silicon oxide, silicon nitride, silicon oxynitride, and/or the low-k material.

The first via V1 may be connected to the first source/drain contact CA1 by penetrating the third interlayer insulating layer 180, the second interlayer insulating layer 175, and the second etch stopper layer 170 in the vertical direction DR3. The second via V2 may be connected to the second source/drain contact CA2 by penetrating the third interlayer insulating layer 180, the second interlayer insulating layer 175, and the second etch stopper layer 170 in the vertical direction DR3. The third via V3 may be connected to the first gate contact CB1 by penetrating the third interlayer insulating layer 180 in the vertical direction DR3. The fourth via V4 may be connected to the second gate contact CB2 by penetrating the third interlayer insulating layer 180 in the vertical direction DR3.

FIGS. 2 through 6 illustrate that the first, second, third, and fourth vias V1, V2, V3, and V4 are formed as single films, but the present disclosure is not limited thereto. Alternatively, in some example embodiments, the first, second, third, and fourth vias V1, V2, V3, and V4 may be formed as multifilms. The first, second, third, and fourth vias V1, V2, V3, and V4 may include a conductive material.

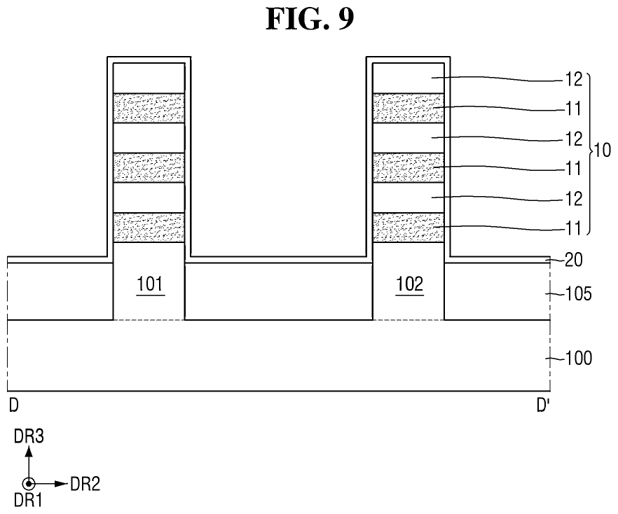

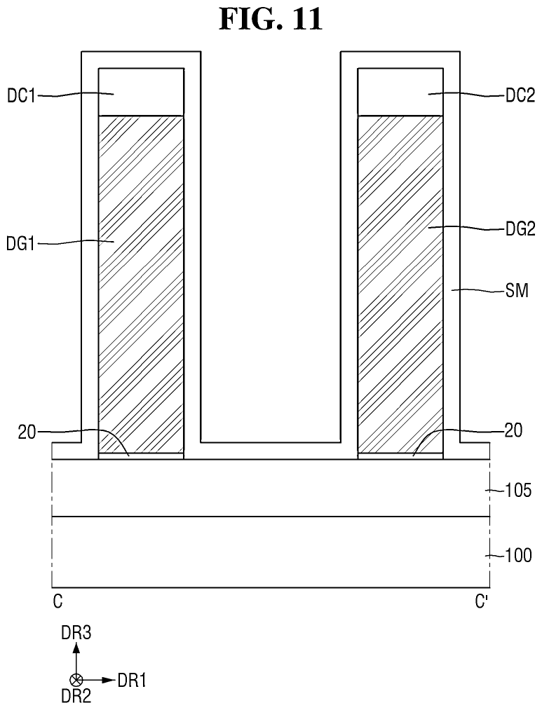

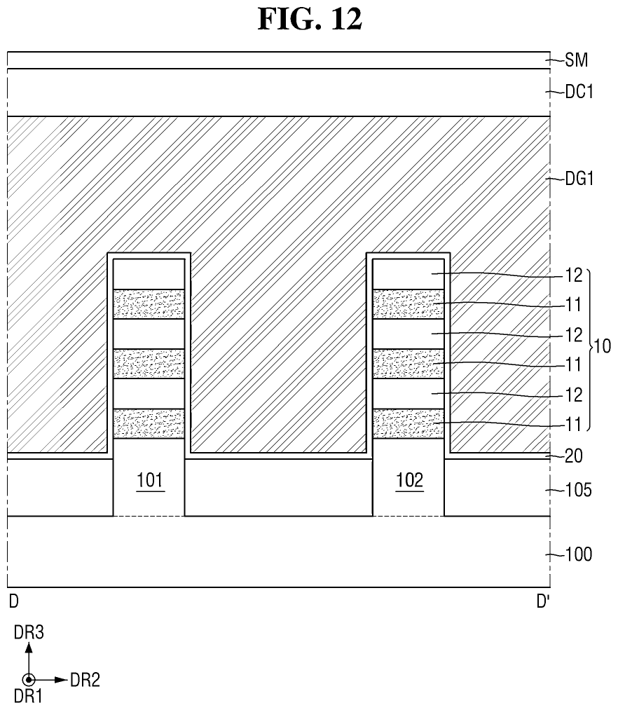

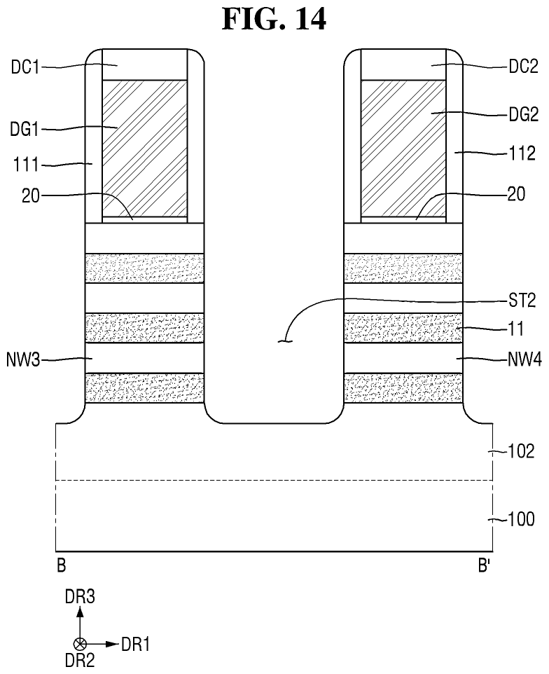

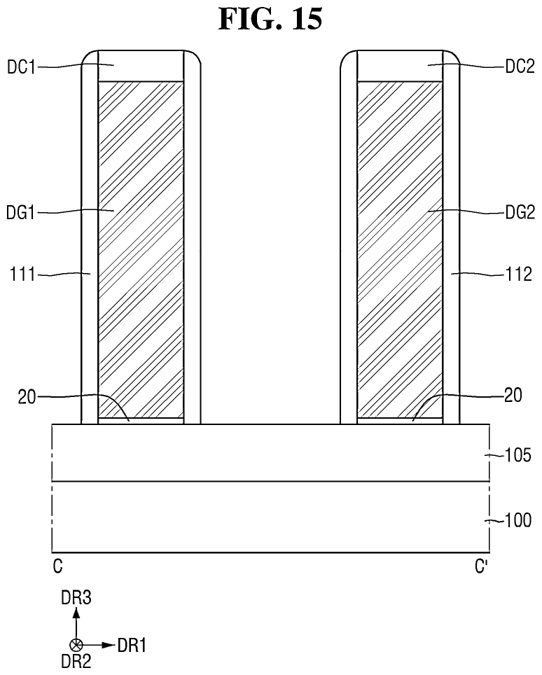

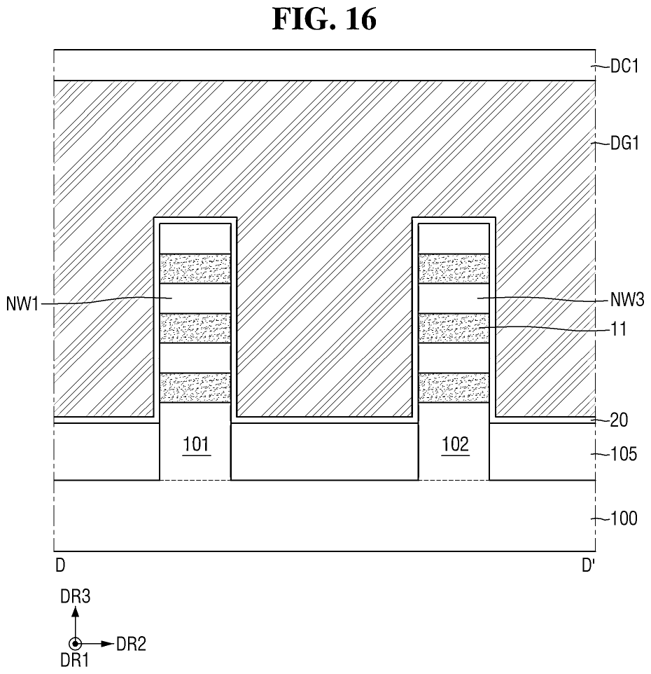

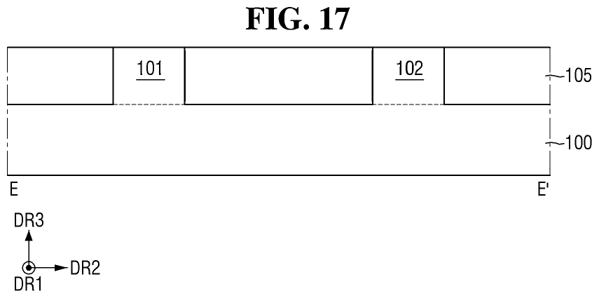

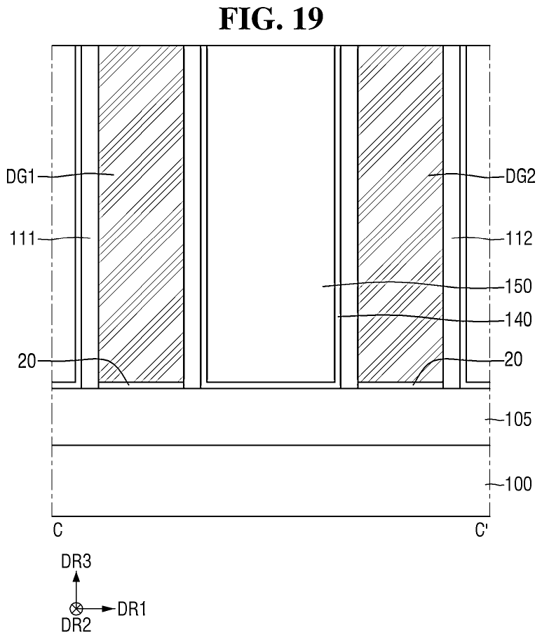

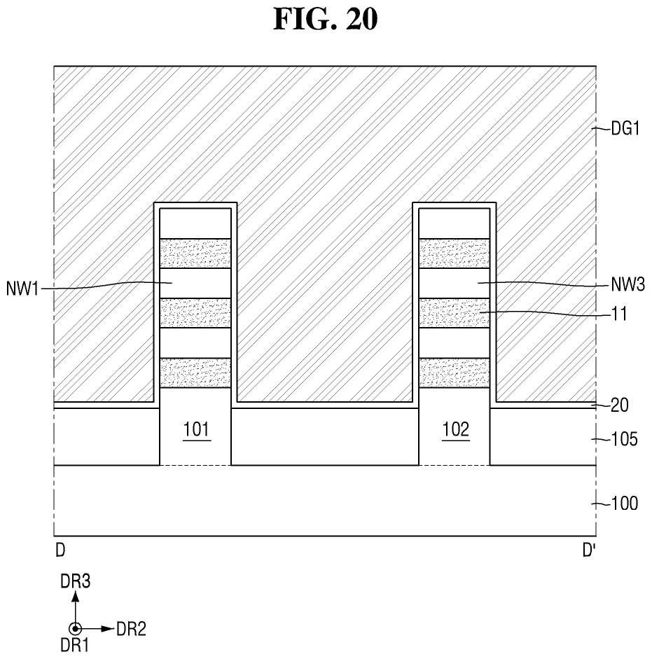

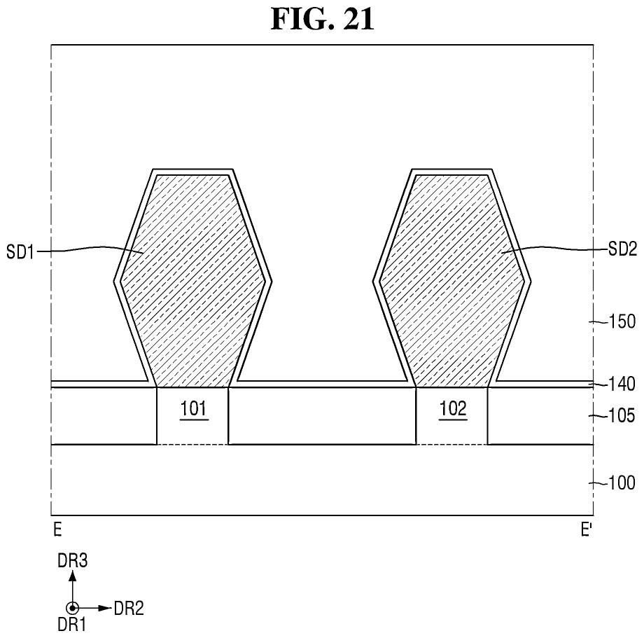

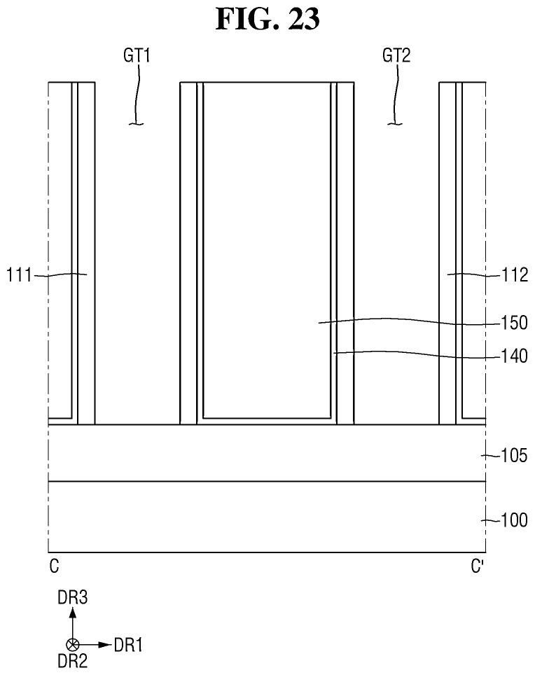

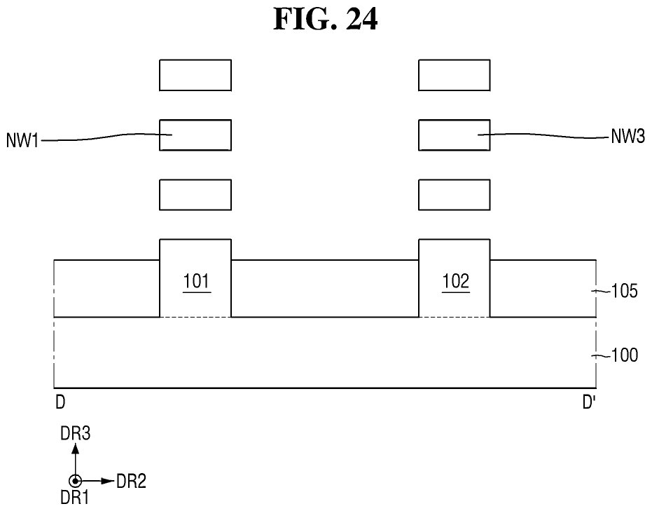

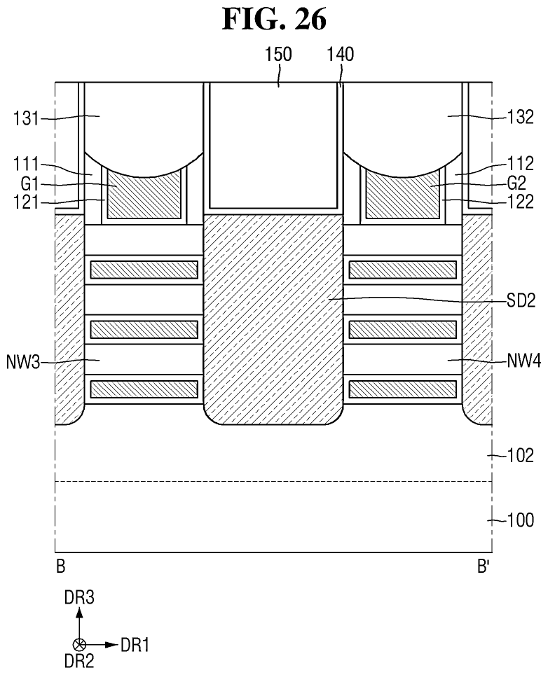

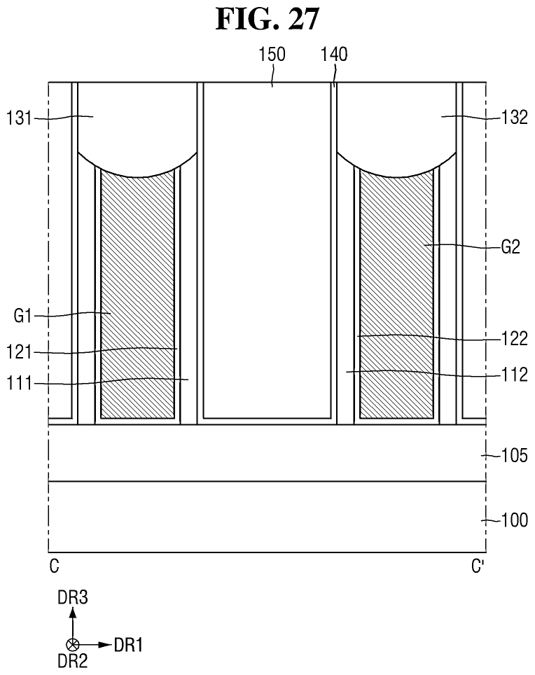

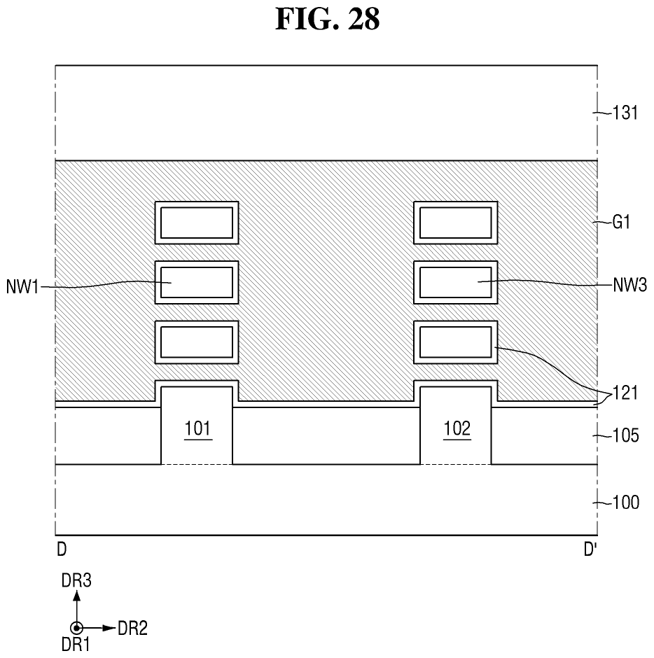

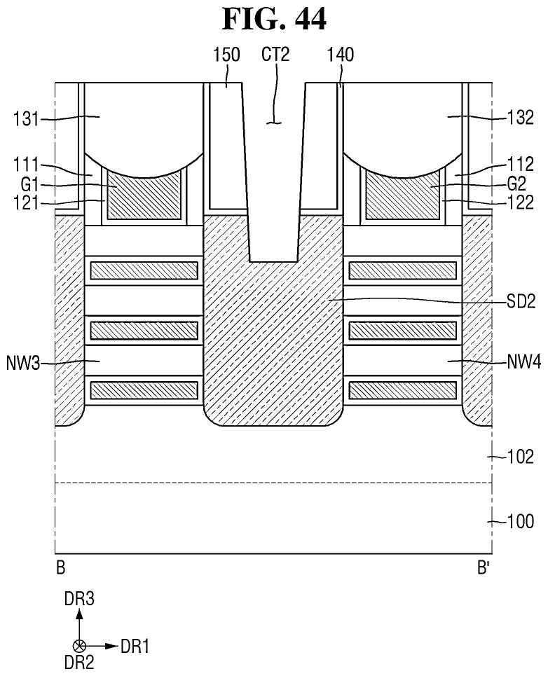

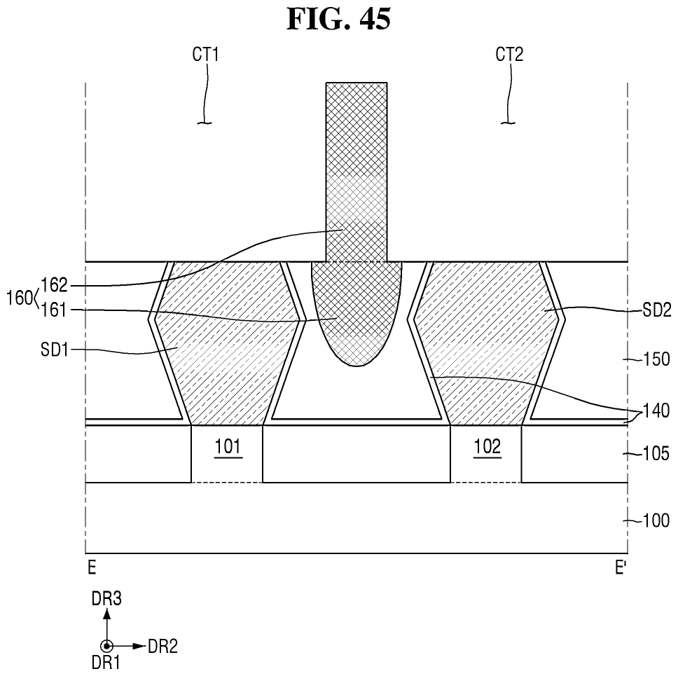

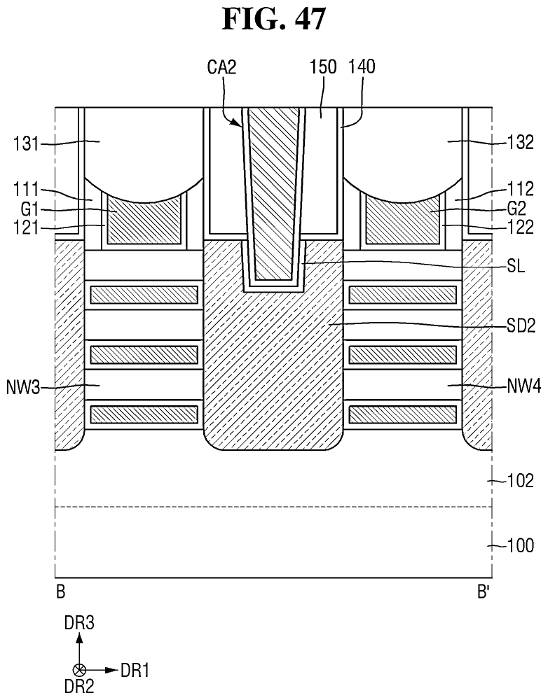

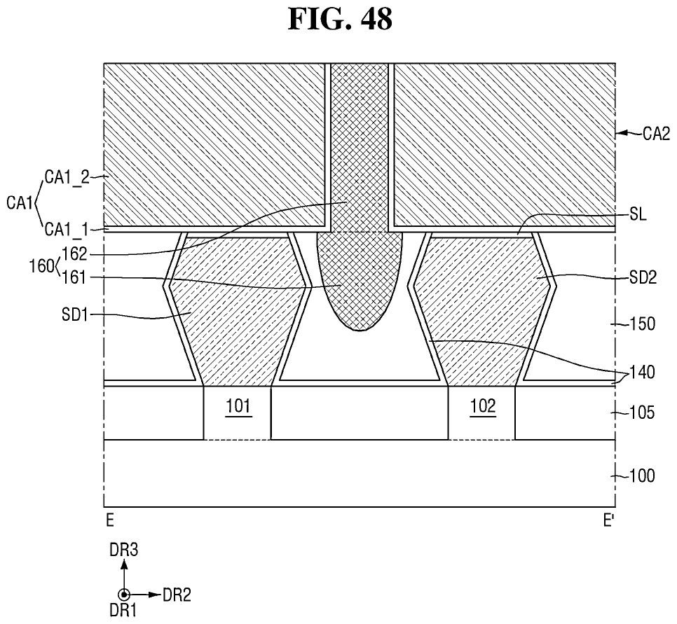

A method of fabricating a semiconductor device according to some example embodiments of the present disclosure will hereinafter be described with reference to FIGS. 2 through 48.

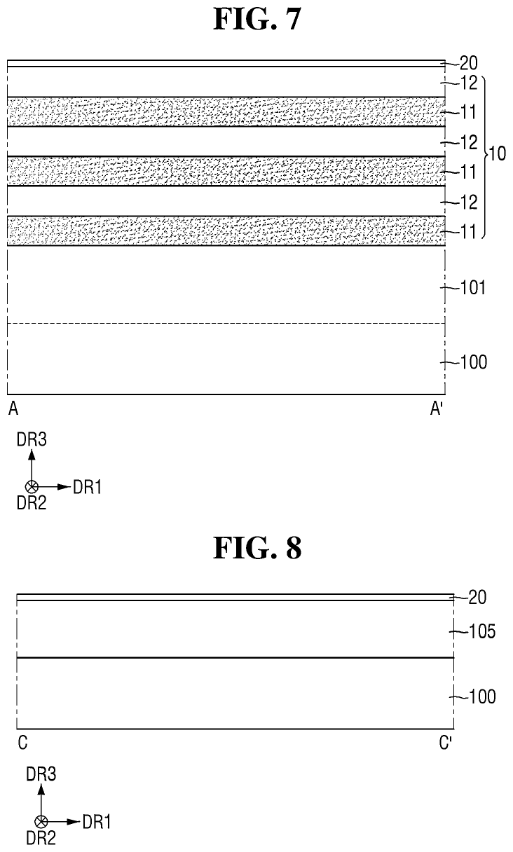

FIGS. 7 through 48 are cross-sectional views illustrating intermediate steps of a method of fabricating a semiconductor device according to some example embodiments of the present disclosure.

Referring to FIGS. 7 through 9, a stack structure 10 may be formed on a substrate 100. The stack structure 10 may include first semiconductor layers 11 and second semiconductor layers 12, which are alternately stacked on the substrate 100. For example, a first semiconductor layer 11 may be formed as the lowermost layer of the stack structure 10, and a second semiconductor layer 12 may be formed as the uppermost layer of the stack structure 10. However, the present disclosure is not limited to this example. Alternatively, in some example embodiments, a first semiconductor layer 11 may also be formed as the uppermost layer of the stack structure 10. The first semiconductor layers 11 may include, for example, SiGe. The second semiconductor layers 12 may include, for example, Si.

Thereafter, part of the stack structure 10 may be etched. When the stack structure 10 is being etched, part of the substrate 100 may also be etched. As a result, first and second active patterns 101 and 102 may be defined below the stack structure 10, on the top surface of the substrate 100. The first and second active patterns 101 and 102 may extend in a first horizontal direction DR1. The second active pattern 102 may be spaced apart from the first active pattern 101 in a second horizontal direction DR2.

Thereafter, a field insulating layer 105 may be formed on the top surface of the substrate 100. The field insulating layer 105 may surround the sidewalls of each of the first and second active patterns 101 and 102. Thereafter, a pad oxide layer 20 may be formed to cover the top surface of the field insulating layer 105, the exposed sidewalls of each of the first and second active patterns 101 and 102, and the sidewalls and top surface of the stack structure 10. For example, the pad oxide layer 20 may be conformally formed. The pad oxide layer 20 may include, for example, SiO₂.

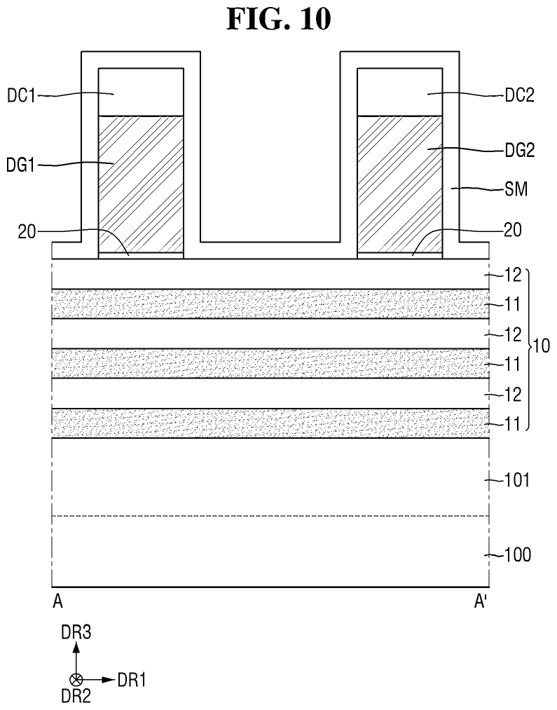

Referring to FIGS. 10 through 12, first and second dummy gates DG1 and DG2, which extend in a second horizontal direction DR2 on the pad oxide layer 20, and first and second dummy capping patterns DC1 and DC2 may be formed on the stack structure 10 and the field insulating layer 105. The first dummy capping pattern DC1 may be formed on the first dummy gate DG1, and the second dummy capping pattern DC2 may be formed on the second dummy gate DG2. The second dummy gate DG2 and the second dummy capping pattern DC2 may be spaced apart in the first horizontal direction DR1 from the first dummy gate DG1 and the first dummy capping pattern DC1, respectively. During the formation of the first and second dummy gates DG1 and DG2 and the first and second dummy capping patterns DC1 and DC2, the entire pad oxide layer 20 except for parts that overlap with the first and second dummy gates DG1 and DG2 in a vertical direction DR3 on the substrate 100 may be removed.

Thereafter, a spacer material layer SM may be formed to cover the sidewalls of each of the first and second dummy gates DG1 and DG2, the sidewalls and top surface of each of the first and second dummy capping patterns DC1 and DC2, and the exposed sidewalls and the top surface of the stack structure 10, and the top surface of the field insulating layer 105. For example, the spacer material layer SM may be conformally formed. The spacer material layer SM may include at least one of, for example, SiN, SiOCN, SiBCN, SiCN, SiON, and/or a combination thereof.

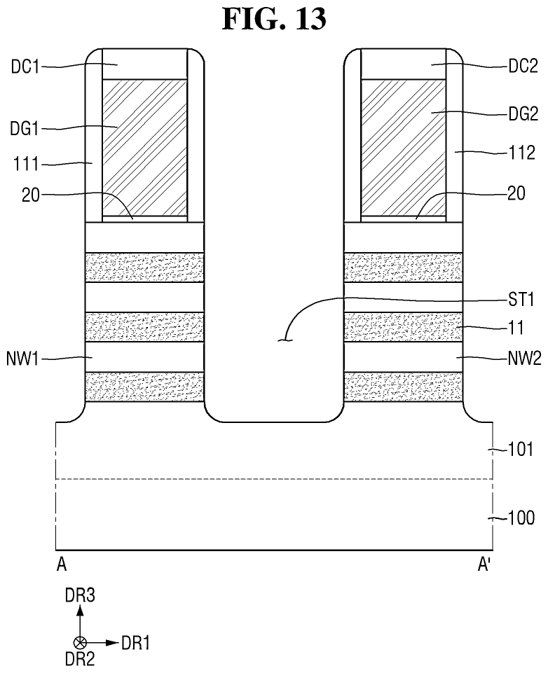

Referring to FIGS. 13 through 17, the stack structure 10 is etched using the first and second dummy gates DG1 and DG2 and the first and second dummy capping patterns DC1 and DC2 as a mask, thereby forming first and second source/drain trenches ST1 and ST2. For example, the first source/drain trench ST1 may be formed on the first active pattern 101 between the first and second dummy gates DG1 and DG2, and the second source/drain trench ST2 may be formed on the second active pattern 102 between the first and second dummy gates DG1 and DG2.

During the formation of the first and second source/drain trenches ST1 and ST2, portions of the spacer material layer SM on the top surfaces of the first and second dummy capping patterns DC1 and DC2 and portions of the first and second dummy capping patterns DC1 and DC2 may be etched. Portions of the spacer material layer SM that remain on the sidewalls of each of the first dummy gates DG1 and DG2 may be defined as first gate spacer 111 and second gate spacer 112. After the formation of the first and second source/drain trenches ST1 and ST2, portions of the second semiconductor layer 12 that remain below the first and second dummy gates DG1 and DG2 may be defined as first plurality of nanosheets NW1, second plurality of nanosheets NW2, third plurality of nanosheets NW3, and fourth plurality of nanosheets NW4.

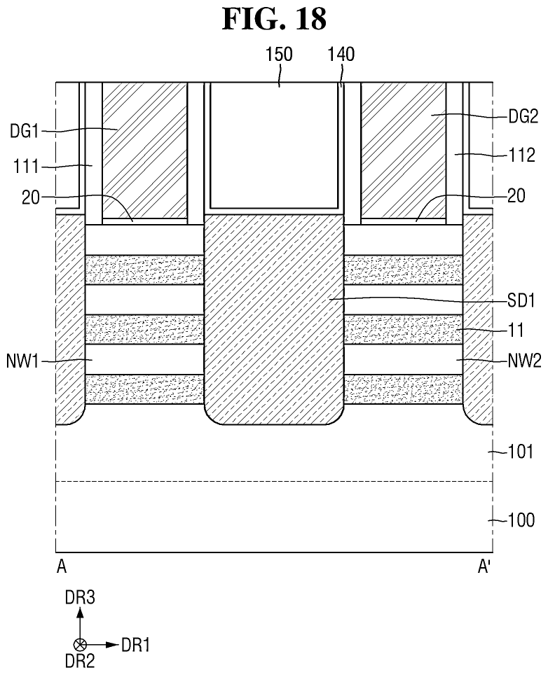

Referring to FIGS. 18 through 21, a first source/drain region SD1 may be formed within the first source/drain trench ST1, and a second source/drain region SD2 may be formed within the second source/drain trench ST2. Thereafter, a first etch stopper layer 140 may be formed on the exposed surface of the field insulating layer 105, the exposed surfaces of the first and second source/drain regions SD1 and SD2, and the exposed sidewalls of each of the first gate spacer 111 and second gate spacer 112. Thereafter, a first interlayer insulating layer 150 may be formed on the first etch stopper layer 140. Thereafter, the top surfaces of the first and second dummy gates DG1 and DG2 may be exposed by performing a planarization process.

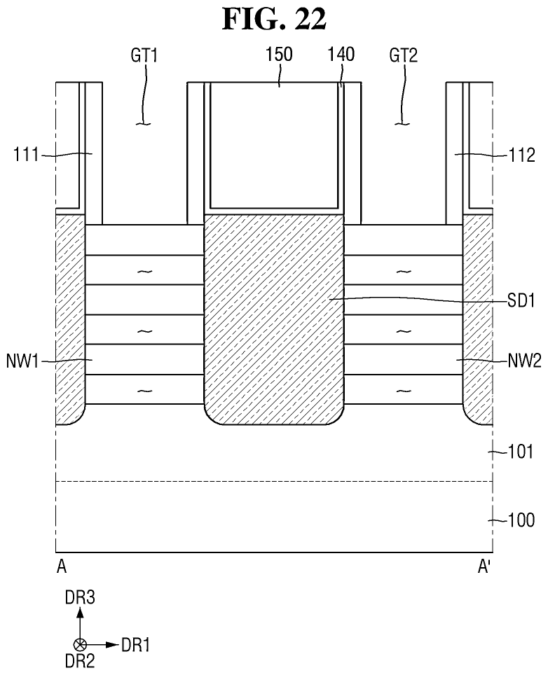

Referring to FIGS. 22 through 24, a first gate trench GT1 may be formed by etching the first dummy gate DG1, the first semiconductor layer 11, and the pad oxide layer 20. Also, a second gate trench GT2 may be formed by etching the second dummy gate DG2, the first semiconductor layer 11, and the pad oxide layer 20.

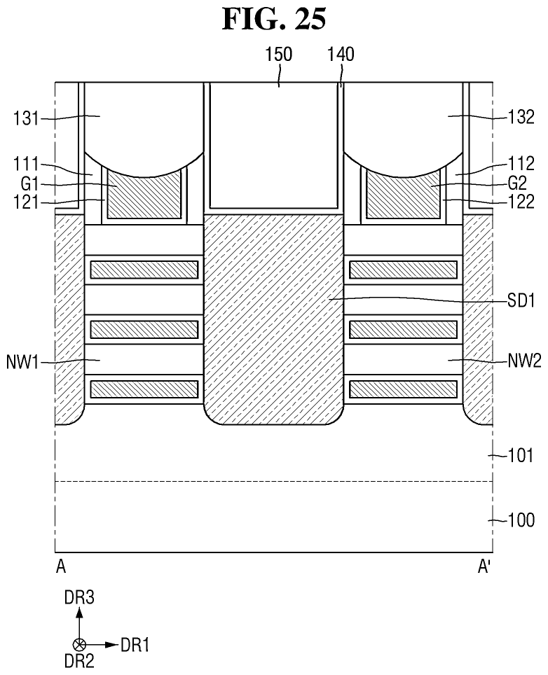

Referring to FIGS. 25 through 28, a first gate insulating layer 121, a first gate electrode G1, and a first capping pattern 131 may be sequentially formed within the first gate trench GT1. Also, a second gate insulating layer 122, a second gate electrode G2, and a second capping pattern 132 may be sequentially formed within the second gate trench GT2.

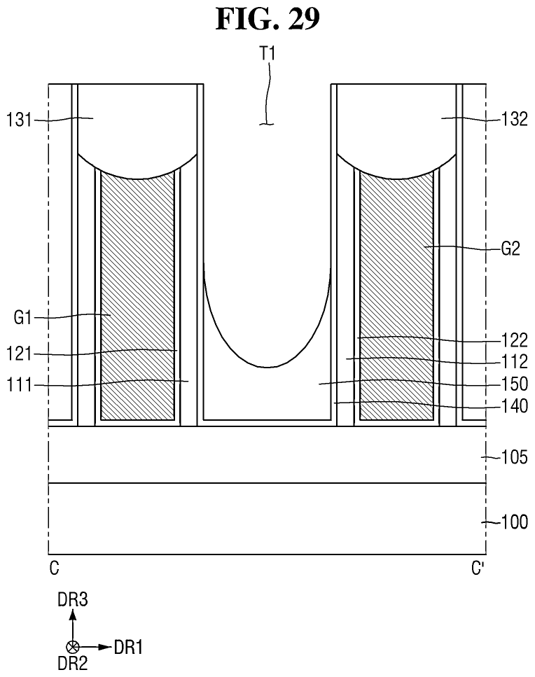

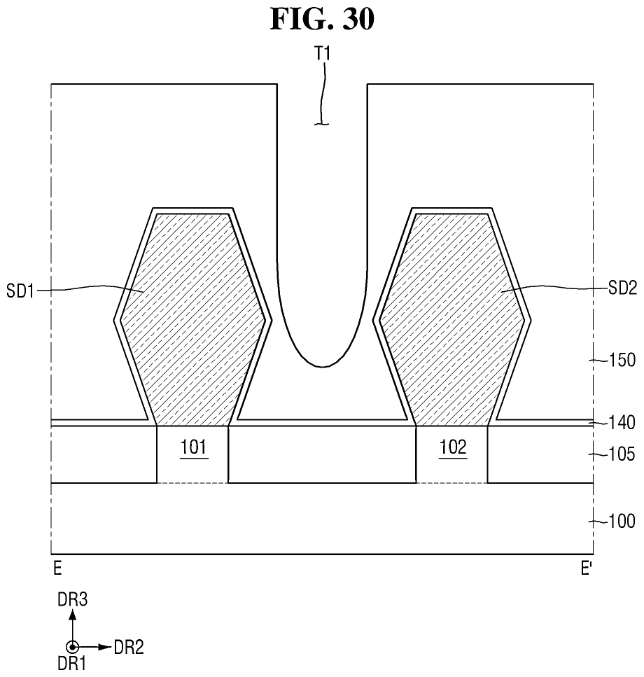

Referring to FIGS. 29 and 30, a first trench T1 may be formed between the first and second source/drain regions SD1 and SD2. The first trench T1 may be formed between the first and second gate electrodes G1 and G2. The first trench T1 may extend from the top surface of the first interlayer insulating layer 150 toward the field insulating layer 105. The bottom surface of the first trench T1 may be defined by the first interlayer insulating layer 150.

For example, the first etch stopper layer 140 may be exposed on both sidewalls, in the first horizontal direction DR1, of the first trench T1. That is, both sidewalls, spaced apart in the first horizontal direction DR1, of the first trench T1 may be defined by the first etch stopper layer 140. For example, both sidewalls, spaced apart in the second horizontal direction DR2, of the first trench T1 may be spaced apart from the first and second source/drain regions SD1 and SD2 in the second horizontal direction DR2. That is, both sidewalls, spaced apart in the second horizontal direction DR2, of the first trench T1 may be defined by the first interlayer insulating layer 150.

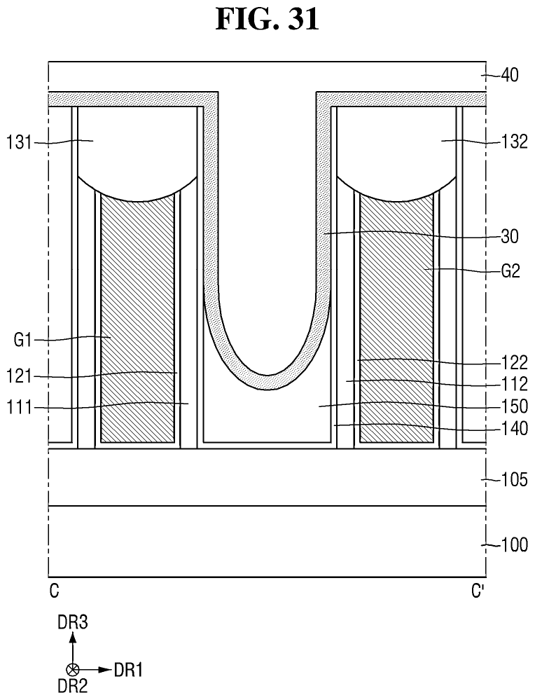

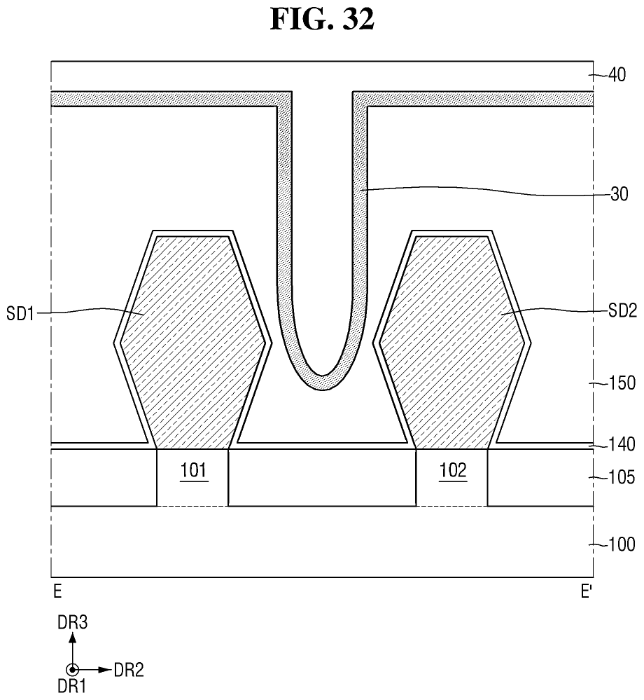

Referring to FIGS. 31 and 32, a first liner layer 30 may be formed along the sidewalls and bottom surface of the first trench T1. The first liner layer 30 may also be formed on the top surfaces of the first interlayer insulating layer 150 and the first and second capping patterns 131 and 132. For example, the first liner layer 30 may be conformally formed. The first liner layer 30 may include at least one of, for example, SiN, SiON, SiO₂, SiCN, SiOCN, and a combination thereof. In some example embodiments, the first liner layer 30 may include a different material from the first and second capping patterns 131 and 132, the first etch stopper layer 140, and the first interlayer insulating layer 150. Thereafter, a sacrificial layer 40 may be formed on the first liner layer 30. The sacrificial layer 40 may include, for example, a spin-on-hardmask (SOH).

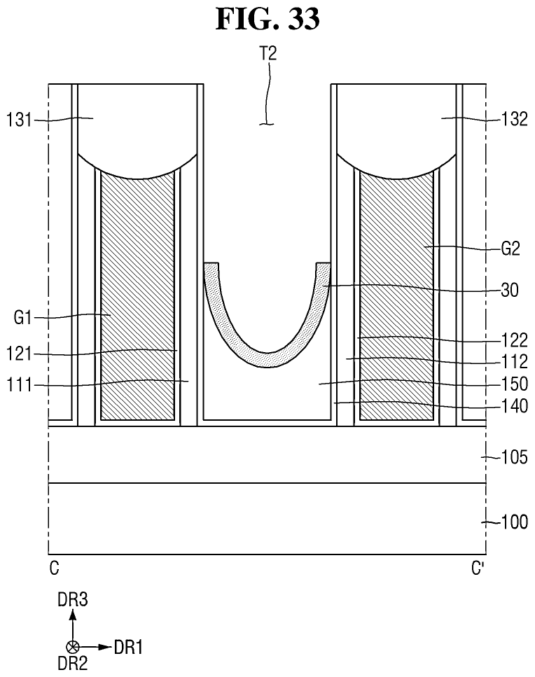

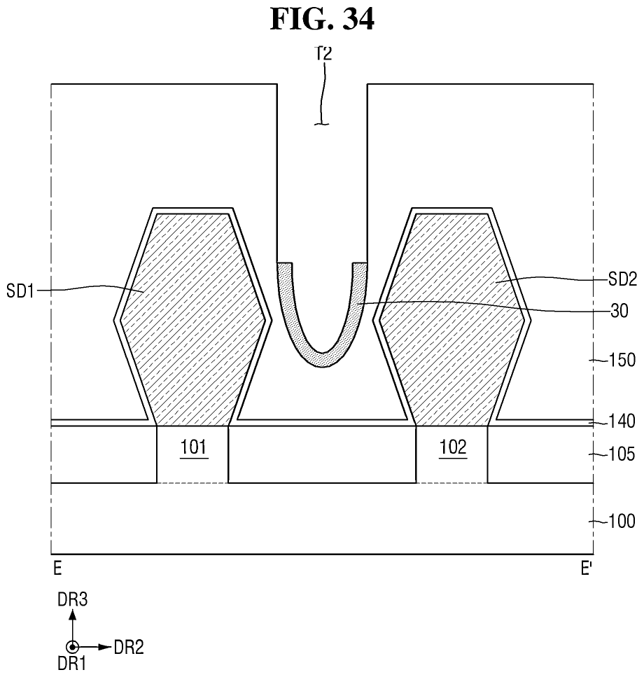

Referring to FIGS. 33 and 34, upper portions of the first liner layer 30 and the sacrificial layer 40 may be partially etched by performing an etch-back process. For example, after the etch-back process, the uppermost surfaces of the first liner layer 30 may become lower than the top surfaces of the first and second source/drain regions SD1 and SD2. Thereafter, the remaining sacrificial layer 40 may be removed. In this manner, a second trench T2 may be formed on the first liner layer 30. The second trench T2 may be defined by the exposed sidewalls of the first etch stopper layer 140, the exposed sidewalls of the first interlayer insulating layer 150, and the exposed surface of the first liner layer 30.

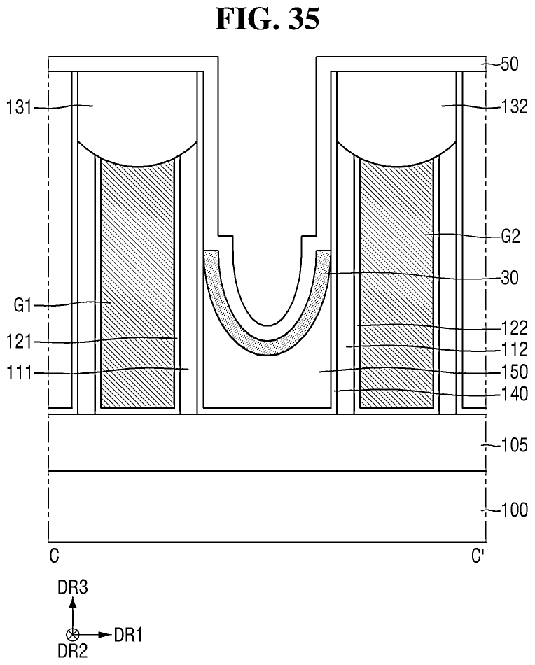

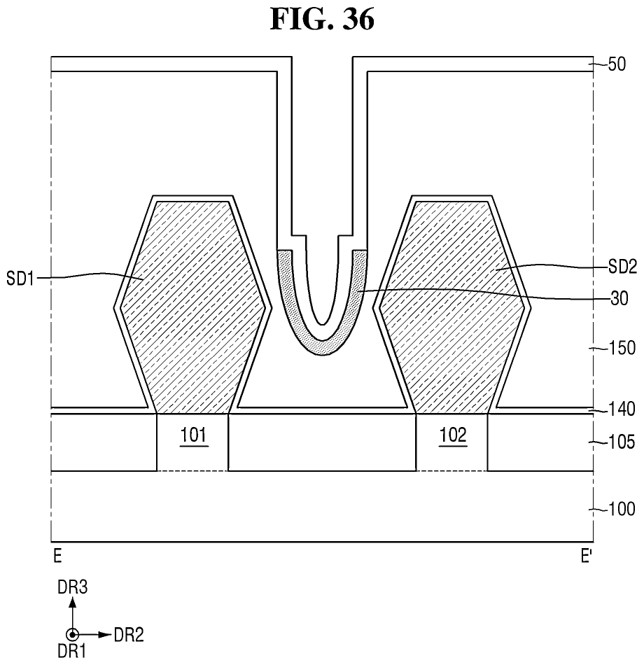

Referring to FIGS. 35 and 36, a second liner layer 50 may be formed along the sidewalls and bottom surface of the second trench T2. The second liner layer 50 may be formed on the surface of the first liner layer 30, exposed by the second trench T2. The second liner layer 50 may be formed on the top surfaces of the first interlayer insulating layer 150 and the first and second capping patterns 131 and 132. For example, the second liner layer 50 may be conformally formed. The second liner layer 50 may include, for example, SiO₂.

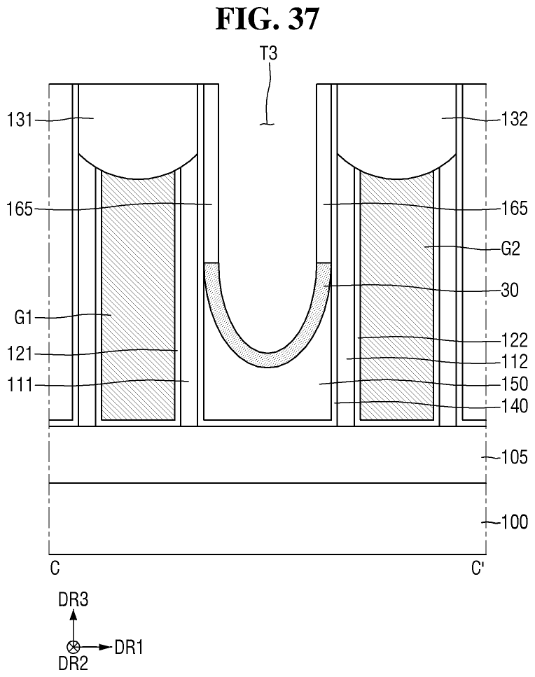

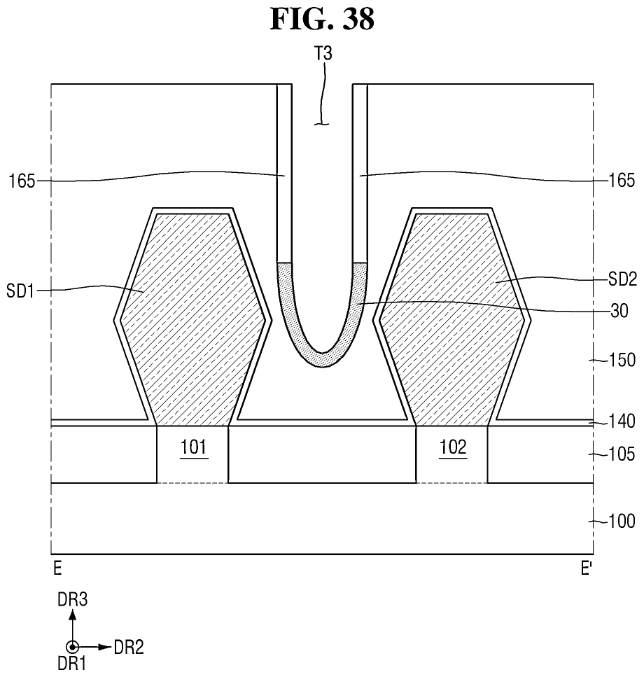

Referring to FIGS. 37 and 38, the first liner layer 30 may be exposed by partially etching the second liner layer 50. For example, portions of the second liner layer 50 that remain on the top surfaces of the first interlayer insulating layer 150 and the first and second capping patterns 131 and 132 may be etched. The remaining second liner layer 50 may extend from the uppermost surfaces of the first liner layer 30 to the top surface of the first interlayer insulating layer 150. The remaining second liner layer 50 may be defined as a liner layer 165. Thereafter, a third trench T3, which is defined by the first liner layer 30 and the liner layer 165, may be formed.

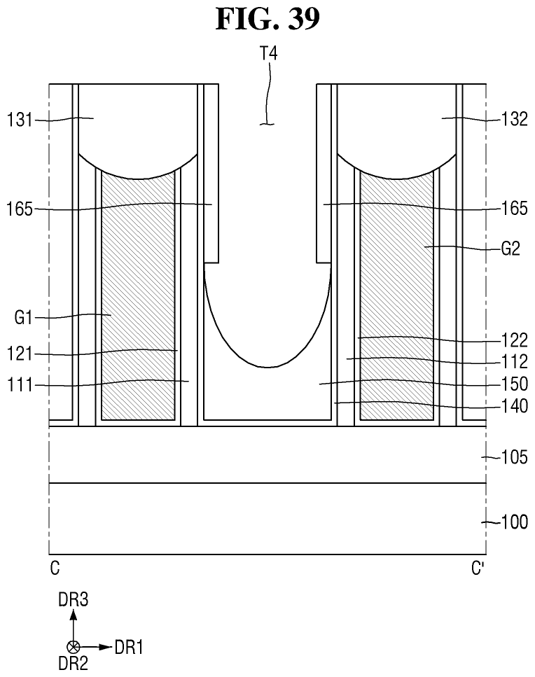

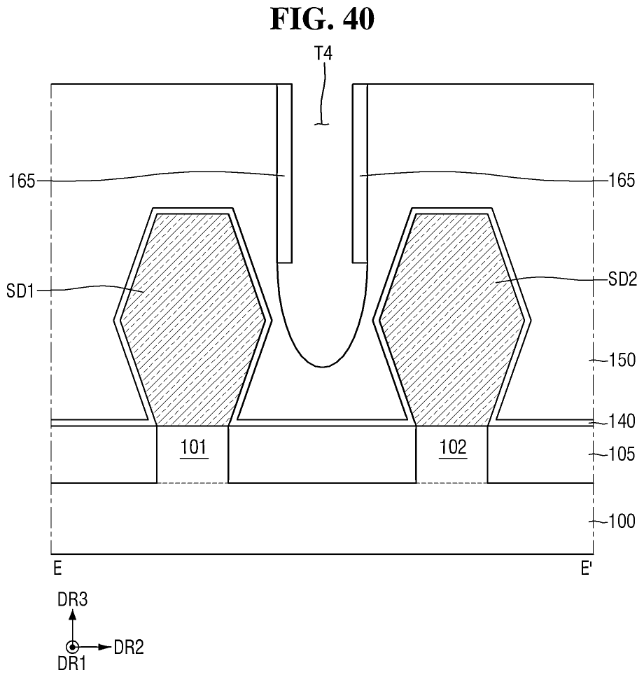

Referring to FIGS. 39 and 40, the first liner layer 30 may be etched. For example, the first liner layer 30 may be etched by a wet etching process. After the etching of the first liner layer 30, a fourth trench T4, which is defined by the exposed surface of the first interlayer insulating layer 150 and the exposed sidewalls and bottom surface of the liner layer 165, may be formed.

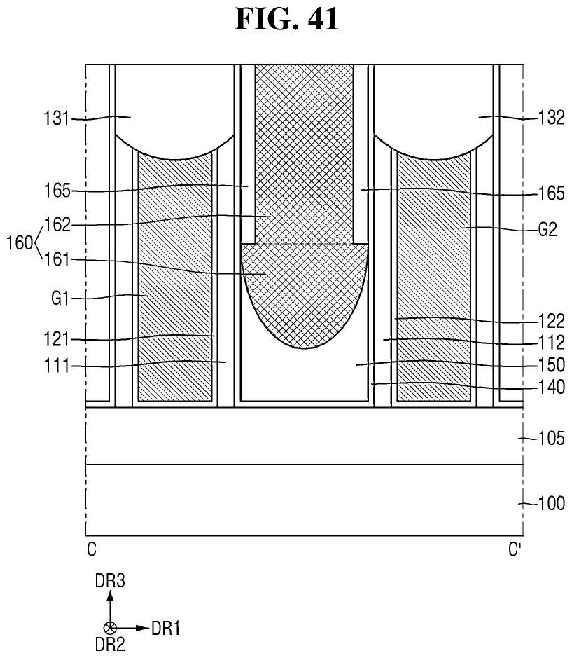

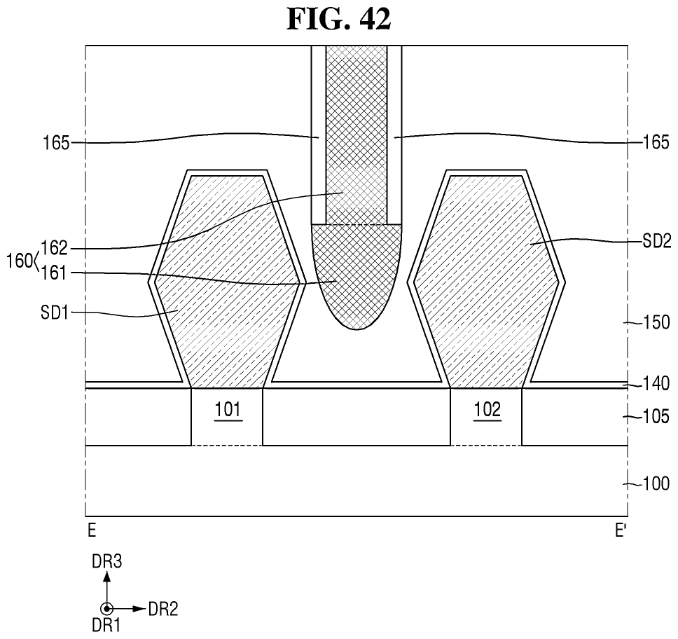

Referring to FIGS. 41 and 42, a contact separation layer 160 may be formed within the fourth trench T4. The contact separation layer 160 may include a first portion 161 and a second portion 162, which is formed on the first portion 161. The second portion 162 of the contact separation layer 160 may be formed between the sidewalls of the liner layer 165. The first portion of the contact separation layer 160 may be formed below the second portion 162 of the contact separation layer 160 and the liner layer 165. The first portion 161 of the contact separation layer 160 may be formed in a region from which the first liner layer 30 has been removed. For example, the width, in the first horizontal direction DR1, of the first portion 161 of the contact separation layer 160 may be greater than the width, in the first horizontal direction DR1, of the second portion 162 of the contact separation layer 160. For example, the width, in the second horizontal direction DR2, of the first portion 161 of the contact separation layer 160 may be greater than the width, in the second horizontal direction DR2, of the second portion 162 of the contact separation layer 160.

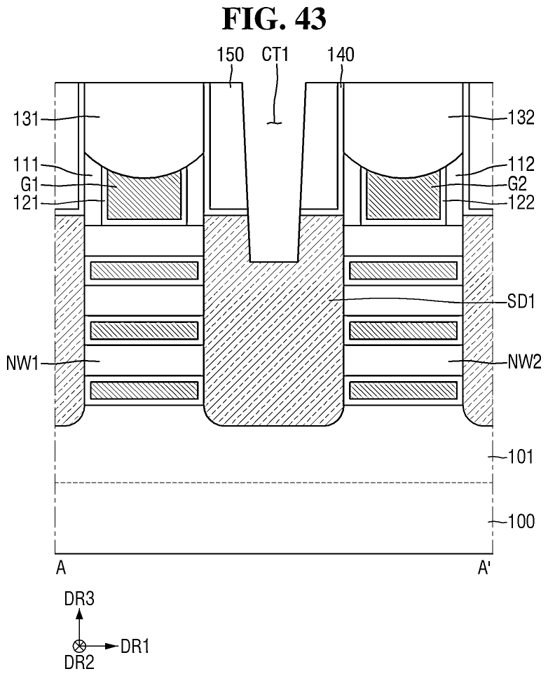

Referring to FIGS. 43 through 45, a first contact trench CT1, which extends in the second horizontal direction DR2, may be formed between the first and second gate electrodes G1 and G2. The first contact trench CT1 may extend into the first source/drain region SD1 by penetrating the first interlayer insulating layer 150 and the first etch stopper layer 140 in the vertical direction DR3. Also, a second contact trench CT2, which extends in the second horizontal direction DR2, may be formed between the first and second gate electrodes G1 and G2. The second contact trench CT2 may be spaced apart from the first contact trench CT1 in the second horizontal direction DR2. The first and second contact trenches CT1 and CT2 may be separated by the second portion 162 of the contact separation layer 160 in the second horizontal direction DR2. The second contact trench CT2 may extend into the second source/drain region SD2 by penetrating the first interlayer insulating layer 150 and the first etch stopper layer 140 in the vertical direction DR3.

For example, during the formation of the first and second contact trenches CT1 and CT2, portions of the liner layer 165 on both sidewalls, spaced apart in the second horizontal direction DR2, of the second portion 162 of the contact separation layer 160 may be etched. As a result, both sidewalls, spaced apart in the second horizontal direction DR2, of the second portion 162 of the contact separation layer 160 and portions of the top surface of the first portion 161 of the contact separation layer 160 may be exposed within the first and second contact trenches CT1 and CT2.

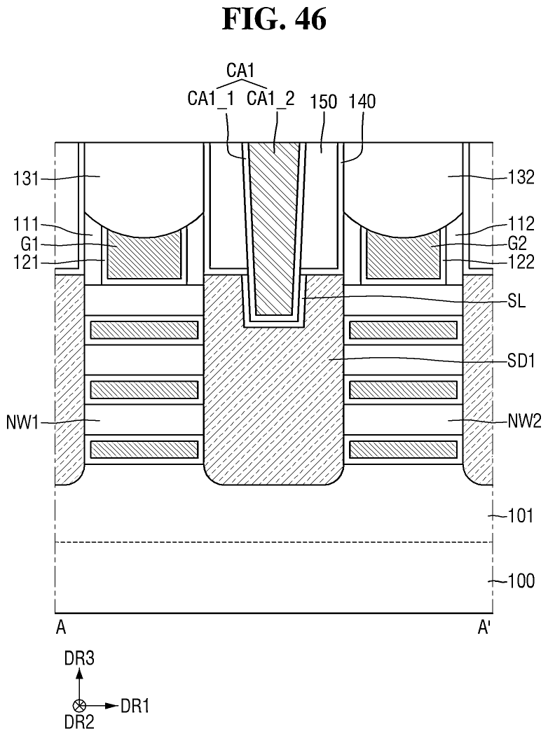

Referring to FIGS. 46 through 48, a first source/drain contact CA1 may be formed within the first contact trench CT1. The first source/drain contact CA1 may extend in the second horizontal direction DR2 on the first source/drain region SD1. A second source/drain contact CA2 may be formed within the second contact trench CT2. The second source/drain contact CA2 may extend in the second horizontal direction DR2 on the second source/drain region SD2. For example, each of the first and second source/drain contacts CA1 and CA2 may include a first contact barrier layer CA1_1 And a first contact filling layer CA1_2, which is formed on the first contact barrier layer CA1_1.

Referring again to FIGS. 2 through 6, a second etch stopper layer 170 and a second interlayer insulating layer 175 may be sequentially formed on the top surfaces of the first interlayer insulating layer 150, the contact separation layer 160, the first and second source/drain contacts CA1 and CA2, and the first and second capping patterns 131 and 132. Thereafter, a first gate contact CB1, which is connected to the first gate electrode G1 by penetrating the second interlayer insulating layer 175, the second etch stopper layer 170, and the first capping pattern 131 in the vertical direction DR3, may be formed. Also, a second gate contact CB2, which is connected to the second gate electrode G2 by penetrating the second interlayer insulating layer 175, the second etch stopper layer 170, and the second capping pattern 132 in the vertical direction DR3, may be formed. For example, each of the first and second gate contacts CB1 and CB2 may include a second contact barrier layer CB1_1 and a second contact filling layer CB1_2, which is formed on the second contact barrier layer CB1_1.

Thereafter, a third interlayer insulating layer 180 may be formed on the top surfaces of the first gate contact CB1, the second gate contact CB2, and the second interlayer insulating layer 175. Thereafter, first, second, third, and fourth vias V1, V2, V3, and V4, which are connected to the first source/drain contact CA1, the second source/drain contact CA2, the first gate contact CB1, and the second gate contact CB2, respectively, by penetrating the third interlayer insulating layer 180, the second interlayer insulating layer 175, and the second etch stopper layer 170 in the vertical direction DR3, may be formed. In this manner, the semiconductor device of FIGS. 2 through 6 can be obtained.

According to the example embodiment of FIGS. 7 through 48, the contact separation layer 160 can be formed using the first and second liner layers 30 and 50. Consequently, the contact separation layer 160 can effectively separate the first and second source/drain contacts CA1 and CA2. The width of the first portion 161, which is a lower portion of the contact separation layer 160, may be formed to be greater than the width of the second portion 162 of the contact separation layer 160, which is an upper portion of the contact separation layer 160.

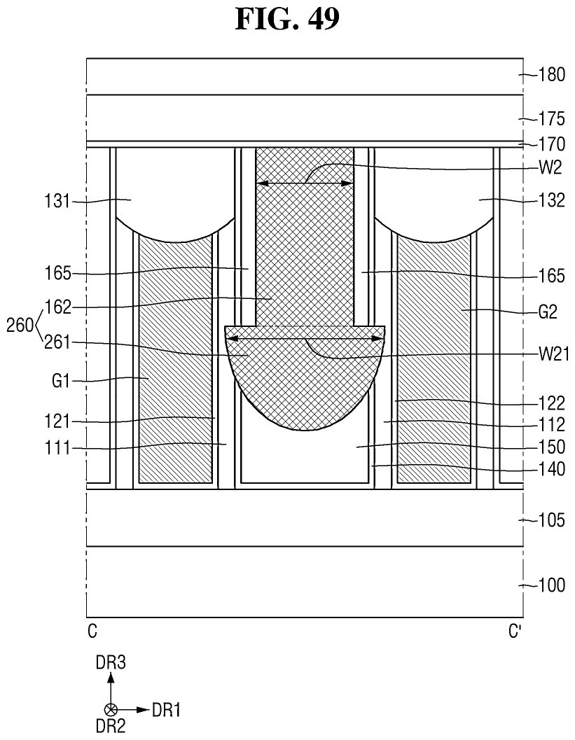

A semiconductor device according to some example embodiments of the present disclosure will hereinafter be described with reference to FIG. 49, highlighting the differences with the semiconductor device of FIGS. 1 through 6.

FIG. 49 is a cross-sectional view of a semiconductor device according to some example embodiments of the present disclosure.

Referring to FIG. 49, a first portion 261 of a contact separation layer 260 may extend into first gate spacer 111 and second gate spacer 112.

For example, at least portions of the sidewalls of the first portion 261 of the contact separation layer 260 may be in contact with the first gate spacer 111 and the second gate spacer 112. At least portions of the top surface of the first portion 261 of the contact separation layer 260 may be in contact with a first etch stopper layer 140, the first gate spacer 111, and the second gate spacer 112. For example, a width W21, in a first horizontal direction DR1, of the first portion 261 of the contact separation layer 260 may be greater than a width W2, in the first horizontal direction DR1, of a second portion 162 of the contact separation layer 260.

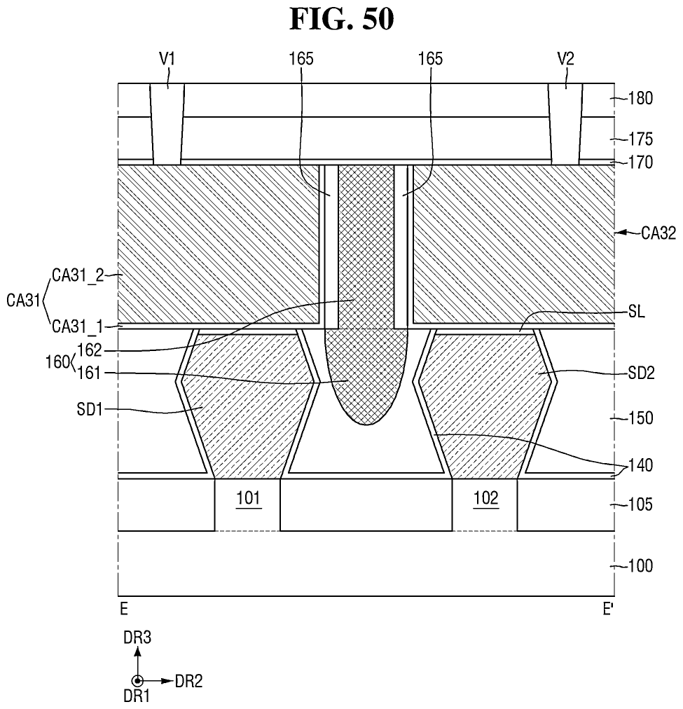

A semiconductor device according to some example embodiments of the present disclosure will hereinafter be described with reference to FIG. 50, highlighting the differences with the semiconductor device of FIGS. 1 through 6.

FIG. 50 is a cross-sectional view of a semiconductor device according to some example embodiments of the present disclosure.

Referring to FIG. 50, a liner layer 165 may be disposed on both sidewalls, spaced apart in a second horizontal direction DR2, of a second portion 162 of a contact separation layer 160.

For example, the liner layer 165 may be disposed between first and second source/drain contacts CA31 and CA32 and both sidewalls, in the second horizontal direction DR2, of the second portion 162 of the contact separation layer 160. The liner layer 165 may be in contact with the first and second source/drain contacts CA31 and CA32 and both sidewalls, spaced apart in the second horizontal direction DR2, of the second portion 162 of the contact separation layer 160. For example, the bottom surface of the liner layer 165 may be in contact with at least portions of the top surface of a first portion 161 of the contact separation layer 160. For example, each of the first and second source/drain contacts CA31 and CA32 may include a first contact barrier layer CA31_1 and a first contact filling layer CA31_2, which is disposed on the first contact barrier layer CA31_1.

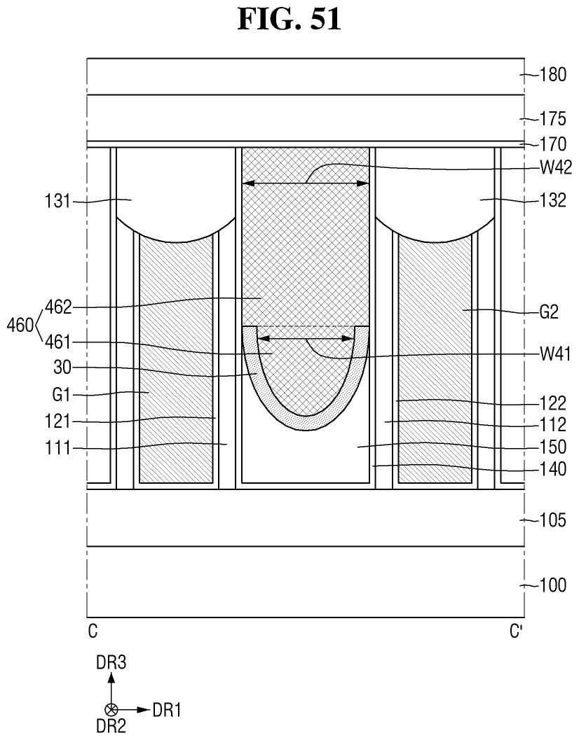

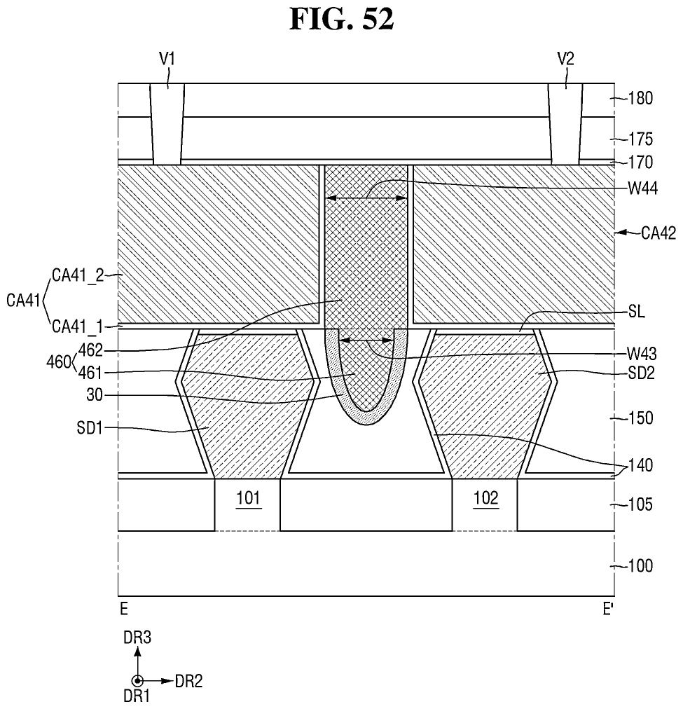

A semiconductor device according to some example embodiments of the present disclosure will hereinafter be described with reference to FIGS. 51 and 52, highlighting the differences with the semiconductor device of FIGS. 1 through 6.

FIGS. 51 and 52 are cross-sectional views of a semiconductor device according to some example embodiments of the present disclosure.

Referring to FIGS. 51 and 52, the width of a first portion 461 of a contact separation layer 460 may be formed to be less than the width of a second portion 462 of the contact separation layer 460.

For example, the first portion 461 of the contact separation layer 460 may be disposed between portions of a first liner layer 30. The sidewalls and bottom surface of the first portion 461 of the contact separation layer 460 may be in contact with the first liner layer 30. The second portion 462 of the contact separation layer 460 may be disposed on the uppermost surfaces of the first liner layer 30 and the top surface of the first portion 461 of the contact separation layer 460. For example, the first liner layer 30 may include a different material from the contact separation layer 460.

For example, both sidewalls, spaced apart in the first horizontal direction DR1, of the second portion 462 of the contact separation layer 460 may be in contact with a first etch stopper layer 140. Both sidewalls, spaced apart in a second horizontal direction DR2, of the second portion 462 of the contact separation layer 460 may be in contact with first and second source/drain contacts CA41 and CA42. For example, each of the first and second source/drain contacts CA41 and CA42 may include a first contact barrier layer CA41_1 and a first contact filling layer CA41_2, which is disposed on the first contact barrier layer CA41_1.

For example, a width W41, in the first horizontal direction DR1, of the first portion 461 of the contact separation layer 460 may be less than a width W42, in the first horizontal direction DR1, of the second portion 462 of the contact separation layer 460. Also, a width W43, in the second horizontal direction DR2, of the first portion 461 of the contact separation layer 460 may be a width W44, in the second horizontal direction DR2, of the second portion 462 of the contact separation layer 460.

A method of fabricating a semiconductor device according to some example embodiments of the present disclosure will hereinafter be described with reference to FIGS. 51 through 56, highlighting the differences with the method of FIGS. 7 through 48.

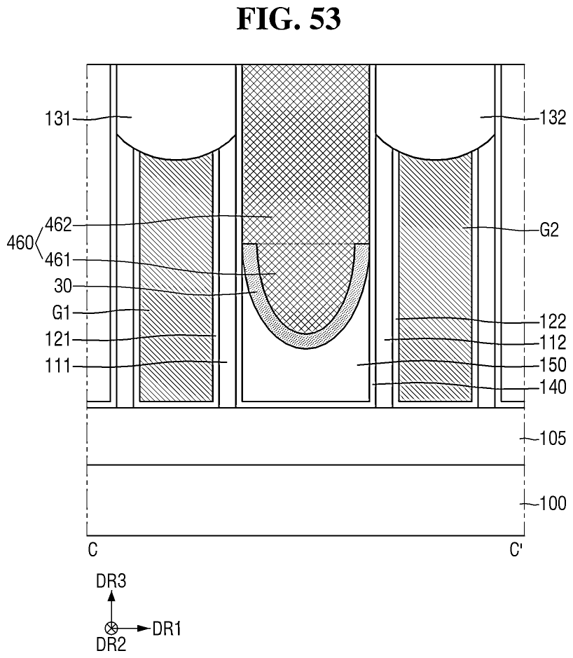

FIGS. 53 through 56 are cross-sectional views illustrating intermediate steps of a method of fabricating a semiconductor device according to some example embodiments of the present disclosure.

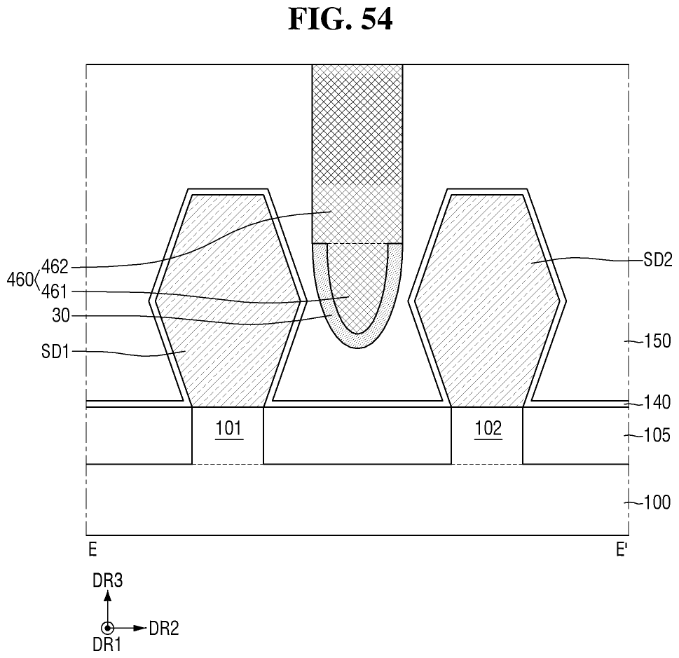

Referring to FIGS. 53 and 54, after the processes depicted in FIGS. 6 through 34, a contact separation layer 460 may be formed on a first liner layer 30 to fill the inside of the second trench T2 of FIGS. 33 and 34. A first portion 461 of the contact separation layer 460 may be formed between portions of the first liner layer 30. A second portion 462 of the contact separation layer 460 may be formed on the uppermost surfaces of the first liner layer 30 and the top surface of the first portion 461 of the contact separation layer 460.

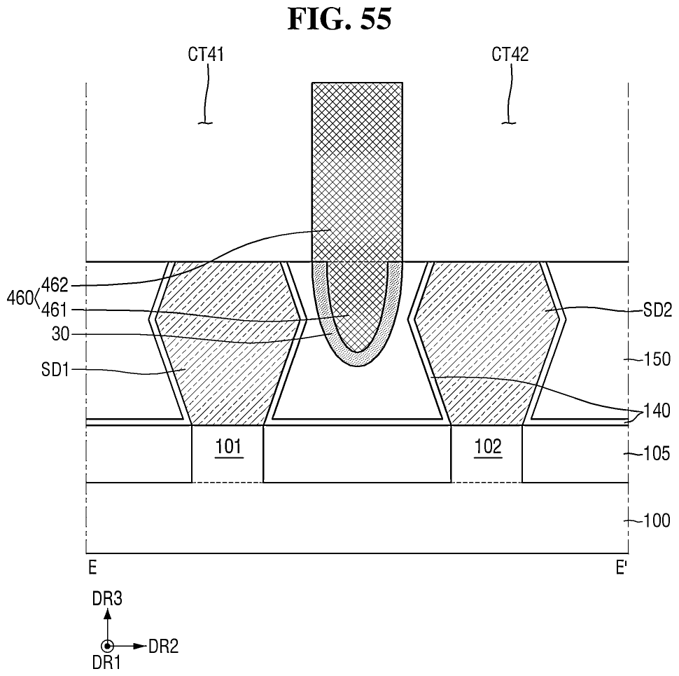

Referring to FIG. 55, a first contact trench CT41, which extends in a second horizontal direction DR2 on a first source/drain region SD1, may be formed. The first contact trench CT41 may extend into the first source/drain region SD1 by penetrating a first interlayer insulating layer 150 and a first etch stopper layer 140 in a vertical direction DR3. Also, a second contact trench CT42, which extends in the second horizontal direction DR2 on a second source/drain region SD2, may be formed. The second contact trench CT42 may be spaced apart from the first contact trench CT41 in the second horizontal direction DR2. The first and second contact trenches CT41 and CT42 may be separated by the second portion 462 of the contact separation layer 460 in the second horizontal direction DR2. The second contact trench CT42 may extend into the second source/drain region SD2 by penetrating the first interlayer insulating layer 150 and the first etch stopper layer 140 in the vertical direction DR3. Both sidewalls, spaced apart in the second horizontal direction DR2, of the second portion 462 of the contact separation layer 460 may be exposed within the first and second contact trenches CT41 and CT42.

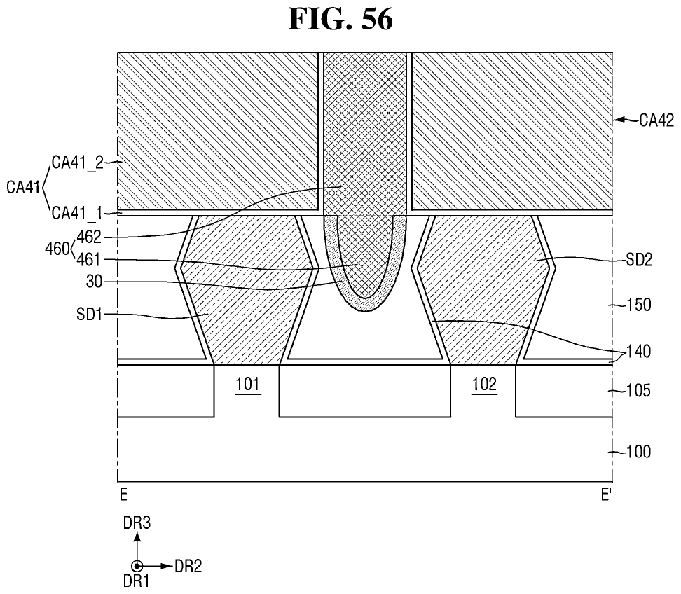

Referring to FIG. 56, a first source/drain contact CA41 may be formed within the first contact trench CT41. The first source/drain contact CA41 may extend in the second horizontal direction DR2 on the first source/drain region SD1. Also, a second source/drain contact CA42 may be formed within the second contact trench CT42. The second source/drain contact CA42 may extend in the second horizontal direction DR2 on the second source/drain region SD2. For example, each of the first and second source/drain contacts CA41 and CA42 may include a first contact barrier layer CA41_1 and a first contact filling layer CA41_2, which is formed on the first contact barrier layer CA41_1.

Referring to FIGS. 51 and 52, a second etch stopper layer 170, a second interlayer insulating layer 175, and a third interlayer insulating layer 180 may be sequentially formed on the top surfaces of the first interlayer insulating layer 150, the contact separation layer 460, the first and second source/drain contacts CA41 and CA42, and the first and second capping patterns 131 and 132. Thereafter, first and second vias V1 and V2, which are connected to the first and second source/drain contacts CA41 and CA42, respectively, may be formed by penetrating the third interlayer insulating layer 180, the second interlayer insulating layer 175, and the second etch stopper layer 170 in the vertical direction DR3. In this manner, the semiconductor device of FIGS. 51 and 52 can be obtained.

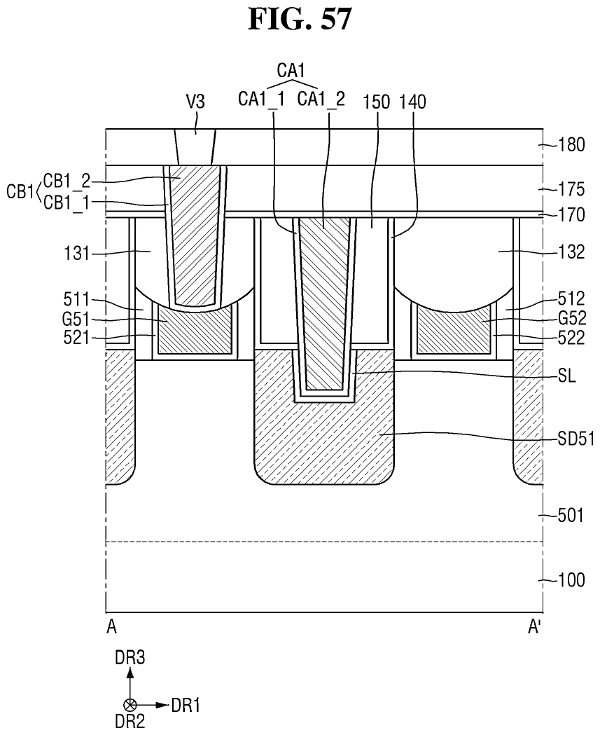

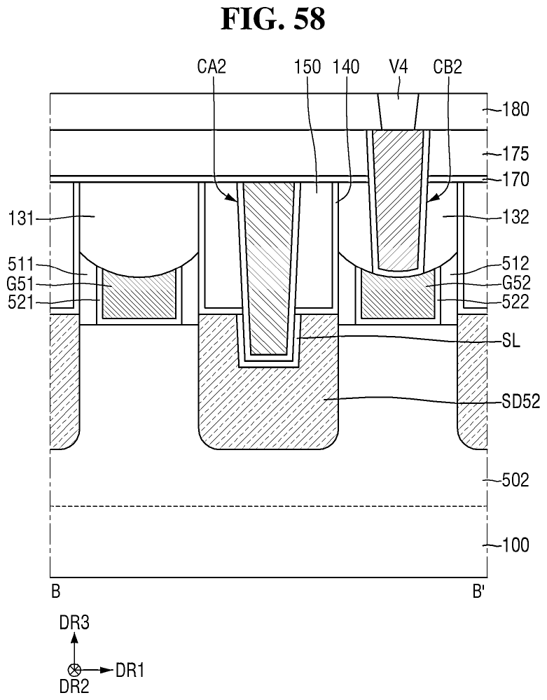

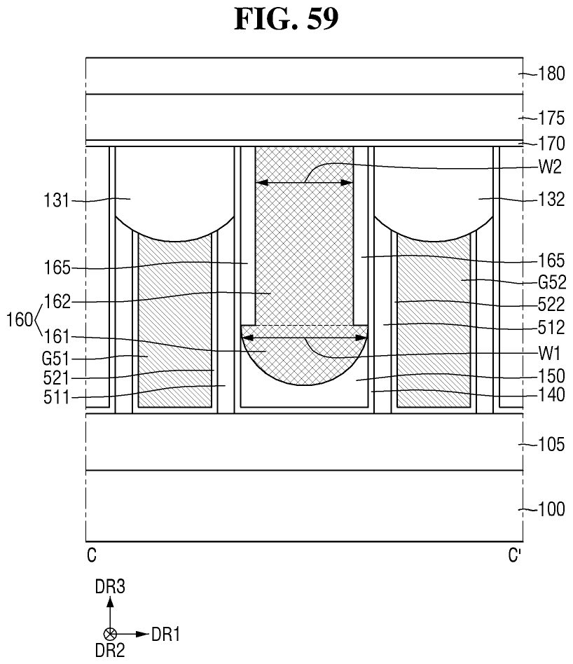

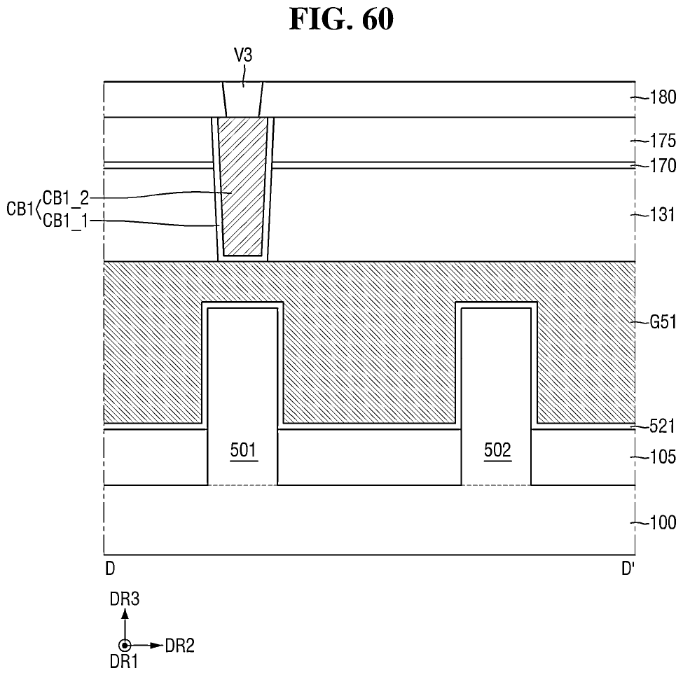

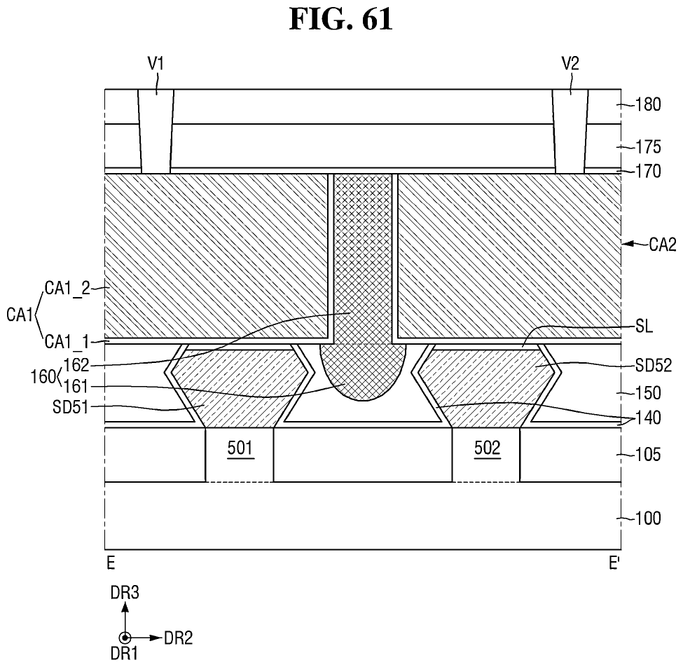

A semiconductor device according to some example embodiments of the present disclosure will hereinafter be described with reference to FIGS. 57 through 61, highlighting the differences with the semiconductor device of FIGS. 1 through 6.

FIGS. 57 through 61 are cross-sectional views illustrating intermediate steps of a method of fabricating a semiconductor device according to some example embodiments of the present disclosure.

Referring to FIGS. 57 through 61, the semiconductor device according to some example embodiments of the present disclosure may include a FinFET. For example, the semiconductor device according to some example embodiments of the present disclosure may include a substrate 100, first and second active patterns 501 and 502, a field insulating layer 105, first and second gate electrodes G51 and G52, first gate spacer 511, second gate spacer 512, first and second gate insulating layers 521, 522, first and second capping patterns 131 and 132, first and second source/drain regions SD51 and SD52, a first etch stopper layer 140, a first interlayer insulating layer 150, first and second source/drain contacts CA1 and CA2, a silicide layer SL, a contact separation layer 160, a liner layer 165, a second etch stopper layer 170, a second interlayer insulating layer 175, first and second gate contacts CB1 and CB2, a third interlayer insulating layer 180, and first, second, third, and fourth vias V1, V2, V3, and V4. Descriptions of the configurations that have already been described with reference to FIGS. 1 through 6 will be omitted.

The first and second active patterns 501 and 502 may extend in a first horizontal direction DR1 on the top surface of the substrate 100. The second active pattern 502 may be spaced apart from the first active pattern 501 in a second horizontal direction DR2. The first gate electrode G51 may extend in the second horizontal direction DR2 on the first active pattern 501, the second active pattern 502, and the field insulating layer 105. The second gate electrode G52 may extend in the second horizontal direction DR2 on the first active pattern 501, the second active pattern 502, and the field insulating layer 105. The second gate electrode G52 may be spaced apart from the first gate electrode G51 in the first horizontal direction DR1. The first gate spacer 511 may extend in the second horizontal direction DR2 along both sidewalls, spaced apart in the first horizontal direction DR1, of the first gate electrode G51 on the first active pattern 501, the second active pattern 502, and the field insulating layer 105. The second gate spacer 512 may extend in the second horizontal direction DR2 along both sidewalls, spaced apart in the first horizontal direction DR1, of the second gate electrode G52 on the first active pattern 501, the second active pattern 502, and the field insulating layer 105.

The first gate insulating layer 521 may be disposed between the first gate electrode G51 and the first and second active patterns 501 and 502. The first gate insulating layer 521 may be disposed between the first gate electrode G51 and the field insulating layer 105. The first gate insulating layer 521 may be disposed between the first gate electrode G51 and the first gate spacer 511. The second gate insulating layer 522 may be disposed between the second gate electrode G52 and the first and second active patterns 501 and 502. The second gate insulating layer 522 may be disposed between the second gate electrode G52 and the field insulating layer 105. The second gate insulating layer 522 may be disposed between the second gate electrode G52 and the second gate spacer 512. The first source/drain region SD51 may be disposed on both sides of each of the first and second gate electrodes G51 and G52 on the first active pattern 501. The second source/drain region SD52 may be disposed on both sides of each of the first and second gate electrodes G51 and G52 on the second active pattern 502.

Example embodiments of the present disclosure have been described above with reference to the accompanying drawings, but the present disclosure is not limited thereto and may be implemented in various different forms. It will be understood that the present disclosure can be implemented in other specific forms without changing the technical spirit or gist of the present disclosure. Therefore, it should be understood that the example embodiments set forth herein are illustrative in all respects and not limiting.

What is claimed is:

1. A semiconductor device comprising:
a substrate;
first and second active patterns extending in a first horizontal direction on the substrate, and the second active pattern spaced apart from the first active pattern in a second horizontal direction different from the first horizontal direction;
a gate electrode extending in the second horizontal direction on the first and second active patterns;
a first source/drain region on one side of the gate electrode on the first active pattern;
a second source/drain region on one side of the gate electrode on the second active pattern;
a first source/drain contact extending in the second horizontal direction on the first source/drain region, the first source/drain contact connected to the first source/drain region;
a second source/drain contact extending in the second horizontal direction on the second source/drain region, the second source/drain contact connected to the second source/drain region, the second source/drain contact spaced apart from the first source/drain contact in the second horizontal direction; and
a contact separation layer separating the first and second source/drain contacts, the contact separation layer including a first portion between the first and second source/drain regions, and a second portion on the first portion between the first and second source/drain regions, wherein a width of the first portion of the contact separation layer in the first horizontal direction is greater than a width of the second portion of the contact separation layer in the first horizontal direction.

2. The semiconductor device of claim 1, wherein a width of the first portion of the contact separation layer in the second horizontal direction is greater than a width of the second portion of the contact separation layer in the second horizontal direction.

3. The semiconductor device of claim 1, further comprising:
an interlayer insulating layer surrounding sidewalls and a bottom surface of the first portion of the contact separation layer, the interlayer insulating layer in contact with the first portion of the contact separation layer, the interlayer insulating layer including a different material from the first portion of the contact separation layer.

4. The semiconductor device of claim 1, further comprising:
a field insulating layer surrounding sidewalls of each of the first and second active patterns on the substrate;
a gate spacer extending in the second horizontal direction on both sidewalls of the gate electrode in the first horizontal direction; and
an etch stopper layer on sidewalls of the gate spacer and a top surface of the field insulating layer,
wherein sidewalls of the second portion of the contact separation layer spaced apart in the first horizontal direction are spaced apart from the etch stopper layer in the first horizontal direction.

5. The semiconductor device of claim 4, further comprising:
a liner layer between the etch stopper layer and the sidewalls of the second portion of the contact separation layer in the first horizontal direction,
wherein at least portion of a top surface of the first portion of the contact separation layer is in contact with a bottom surface of the liner layer.

6. The semiconductor device of claim 5, wherein a top surface of the liner layer is on a same plane as a top surface of the second portion of the contact separation layer.

7. The semiconductor device of claim 4, wherein sidewalls of the first portion of the contact separation layer in the first horizontal direction are in contact with the etch stopper layer.

8. The semiconductor device of claim 4, wherein at least a portion of a top surface of the first portion of the contact separation layer is in contact with the gate spacer and the etch stopper layer.

9. The semiconductor device of claim 1, wherein at least a portion of a top surface of the first portion of the contact separation layer is in contact with the first and second source/drain contacts.

10. The semiconductor device of claim 1, further comprising:
a first plurality of nanosheets stacked on the first active pattern spaced apart from one another in a vertical direction, the first plurality of nanosheets surrounded by the gate electrode; and
a second plurality of nanosheets stacked on the second active pattern spaced apart from one another in the vertical direction, the second plurality of nanosheets surrounded by the gate electrode.

11. A semiconductor device comprising:
a substrate;
first and second active patterns extending in a first horizontal direction on the substrate, the second active pattern spaced apart from the first active pattern in a second horizontal direction different from the first horizontal direction;
a field insulating layer surrounding sidewalls of each of the first and second active patterns on the substrate;
a gate electrode extending in the second horizontal direction on the first and second active patterns;
a gate spacer extending in the second horizontal direction on both sidewalls of the gate electrode in the first horizontal direction;
a first source/drain region on one side of the gate electrode on the first active pattern;
a second source/drain region on one side of the gate electrode on the second active pattern;
an etch stopper layer on sidewalls of each of the first and second source/drain regions in the second horizontal direction, sidewalls of the gate spacer and a top surface of the field insulating layer;
a first source/drain contact extending in the second horizontal direction on the first source/drain region, the first source/drain contact connected to the first source/drain region;
a second source/drain contact extending in the second horizontal direction on the second source/drain region, the second source/drain contact connected to the second source/drain region, the second source/drain contact spaced apart from the first source/drain contact in the second horizontal direction;
a contact separation layer separating the first and second source/drain contacts, the contact separation layer including a first portion between the first and second source/drain regions, and a second portion on the first portion between the first and second source/drain regions, wherein a width of the first portion of the contact separation layer in the second horizontal direction is greater than a width of the second portion of the contact separation layer in the second horizontal direction; and
a liner layer between the etch stopper layer and sidewalls of the second portion of the contact separation layer in the first horizontal direction.

12. The semiconductor device of claim 11, wherein a width of the first portion of the contact separation layer in the first horizontal direction is greater than a width of the second portion of the contact separation layer in the first horizontal direction.

13. The semiconductor device of claim 11, wherein a top surface of the liner layer is on a same plane as a top surface of the second portion of the contact separation layer.

14. The semiconductor device of claim 11, wherein the liner layer includes a different material from the contact separation layer.

15. The semiconductor device of claim 11, wherein the liner layer is between the first and second source/drain contacts and the sidewalls of the second portion of the contact separation layer in the second horizontal direction, and
wherein at least portion of a top surface of the first portion of the contact separation layer is in contact with a bottom surface of the liner layer.

16. A method of fabricating a semiconductor device, comprising:
forming first and second active patterns extended in a first horizontal direction on a substrate, the second active pattern spaced apart from the first active pattern in a second horizontal direction different from the first horizontal direction;
forming a field insulating layer surrounding sidewalls of each of the first and second active patterns on the substrate;
forming a dummy gate extended in the second horizontal direction on the first and second active patterns;
forming a gate spacer extended in the second horizontal direction on both sidewalls of the dummy gate in the first horizontal direction;
forming a first source/drain region on one side of the dummy gate on the first active pattern, and forming a second source/drain region on one side of the dummy gate on the second active pattern;
forming an etch stopper layer on surfaces of the first and second source/drain regions, sidewalls of the gate spacer and a top surface of the field insulating layer;
removing the dummy gate;
forming a gate electrode in a region where the dummy gate is removed;
forming a first trench exposing the etch stopper layer on the sidewalls of the gate spacer, between the first and second source/drain regions;
forming a first liner layer along sidewalls and a bottom surface of the first trench;
forming a second trench by partially etching an upper portion of the first liner layer such that a top surface of the first liner layer becomes lower than top surfaces of the first and second source/drain regions;
forming a contact separation layer within the second trench, the contact separation layer including a first portion and a second portion disposed on the first portion; and
forming a first source/drain contact extending in the second horizontal direction on the first source/drain region, and a second source/drain contact extending in the second horizontal direction on the second source/drain region,
wherein the contact separation layer separates the first and second source/drain contacts,
wherein a width of the first portion of the contact separation layer in the first horizontal direction is different from a width of the second portion of the contact separation layer in the first horizontal direction, and
wherein a width of the first portion of the contact separation layer in the second horizontal direction is different from a width of the second portion of the contact separation layer in the second horizontal direction.

17. The method of claim 16, wherein the width of the first portion of the contact separation layer in the first horizontal direction is greater than the width of the second portion of the contact separation layer in the first horizontal direction, and
wherein the width of the first portion of the contact separation layer in the second horizontal direction is greater than the width of the second portion of the contact separation layer in the second horizontal direction.

18. The method of claim 17, wherein the forming the contact separation layer comprises:
forming a second liner layer along sidewalls and a bottom surface of the second trench;
forming a third trench by etching a portion of the second liner layer to expose the first liner layer;
forming a fourth trench by removing the first liner layer; and
forming the contact separation layer within the fourth trench,
wherein the second portion of the contact separation layer is formed between portions of the second liner layer, and
wherein the first portion of the contact separation layer is formed below the second portion of the contact separation layer and in a region where the first liner layer is removed.

19. The method of claim 16, wherein the width of the first portion of the contact separation layer in the first horizontal direction is less than the width of the second portion of the contact separation layer in the first horizontal direction, and
wherein the width of the first portion of the contact separation layer in the second horizontal direction is less than the width of the second portion of the contact separation layer in the second horizontal direction.

20. The method of claim 19, wherein the forming the contact separation layer comprises forming the contact separation layer on the first liner layer to fill an inside of the second trench,
wherein the first portion of the contact separation layer is formed between portions of the first liner layer, and
wherein the second portion of the contact separation layer is formed on a top surface of the first portion of the contact separation layer and an uppermost surface of the first liner layer.
